(19) United States
(12) Patent Application Publication
(10) Pub. No.: US 2018/0373091 A1
(43) Pub. Date: Dec. 27, 2018

(54) DISPLAY PANEL

(71) Applicant: SHARP KABUSHIKI KAISHA, Sakai City, Osaka (JP)

(72) Inventors: KOSUKE NAGATA, Sakai City (JP); MASAYUKI HATA, Sakai City (JP); MIKIHIRO NOMA, Sakai City (JP)

(73) Assignee: SHARP KABUSHIKI KAISHA, Sakai City, Osaka (JP)

(21) Appl. No.: 15/747,067

(22) PCT Filed: Jul. 28, 2016
(86) PCT No.: PCT/JP2016/072131

§ 371 Date: Jan. 23, 2018

(30) Foreign Application Priority Data
Aug. 3, 2015 (JP) 2015-153362

(51) Int. Cl. G02F 1/1335; G02F 1/1362; G02F 1/1333; H01L 27/12; G02F 1/1343; G02F 1/1345

(52) U.S. Cl. CPC G02F 1/133528; G02F 1/133514; G02F 1/136286; G02F 1/13338; H01L 27/124; G02F 2001/134372; G02F 1/134309; G02F 1/13452; G02F 2201/121; G02F 2201/123; H01L 27/1225

(57) ABSTRACT

A display panel 10 includes an array board 10b including TFTs arranged in a matrix, a CF board 10a bonded to the array board 10b to be opposite the array board 10b, a first polarizing plate 10c bonded to the CF board 10a on a plate surface opposite from an array board 10b side, the first polarizing plate 10c including a conductive bonding layer 30 that is bonded to the CF board 10a, a conductive member 31 disposed on the plate surface of the CF board 10a opposite from the array board 10b side and overlapping the conductive bonding layer 30 on a CF board 10a side with respect to the conductive bonding layer 30, and a ground connection member 32 having one end connected to the conductive member 31 and another end connected to ground.

### TECHNICAL FIELD

The present invention relates to a display panel.

### BACKGROUND ART

A liquid crystal display device described in Patent Document 1 has been known. The liquid crystal display device described in Patent Document 1 includes a first substrate and a second substrate that are disposed opposing to each other via a liquid crystal layer, a first polarizing plate, and a second polarizing plate. The second polarizing plate is disposed on a surface on an image display side of the second substrate and the first polarizing plate is disposed on a surface side of the first substrate. A step-like shape is formed by each end of the second polarizing plate, a conductive film, the first substrate, and the first polarizing plate. The liquid crystal display device includes a conductive tape disposed to be formed in the step-like shape and electrically connecting the first polarizing plate and the conductive film to the ground. One end of the conductive tape is electrically connected to an exposed surface of the conductive film, while the other end is electrically connected to a counter surface side of the first polarizing plate exposed from the end of the first substrate. The first polarizing plate is formed of a conductive material having conductivity. Potentials of the conductive film and the first polarizing plate are held at the ground potential.

### RELATED ART DOCUMENT

### Patent Document

Patent Document 1: Japanese Unexamined Patent Application Publication No. 2015-84017

### Problem to be Solved by the Invention

In Patent Document 1, the conductive film formed in an area between the second substrate and the second polarizing plate is made of transparent electrode film material such as ITO. It is preferable to protect the panel from static electricity from an observer side. However, in a configuration of the display panel including an in-cell type touch panel pattern, the touch panel signals may be shielded and touching sensitivity may be lowered. Thus, a function of a touch panel may be deteriorated. Namely, it is difficult to achieve a multifunctional liquid crystal panel.

### DISCLOSURE OF THE PRESENT INVENTION

The present invention was made in view of the above circumstances. An object is to achieve multifunctionality.

### Means for Solving the Problem

A display panel according to the present technology includes an array board including display components arranged in a matrix, a counter board bonded to the array board to be opposite the array board, a polarizing plate bonded to the counter board on a plate surface opposite from an array board side, the polarizing plate including a conductive bonding layer that is bonded to the counter board, a conductive member disposed on the plate surface of the counter board opposite from the array board side and overlapping the conductive bonding layer on a counter board side with respect to the conductive bonding layer, and a ground connection member having one end connected to the conductive member and another end connected to ground.

According to such a configuration, the polarizing plate that is bonded to the plate surface of the counter board opposite from the array board side is bonded to the counter board via the conductive bonding layer. The conductive member that is to be overlapped on the counter board side is connected to the conductive bonding layer. The conductive member is connected to one end of the ground connection member. The other end of the ground connection member is connected to ground. Therefore, static electricity is likely to remain in comparison to the array board, and the counter board that is likely to be adversely affected by the static electricity is properly shielded by the conductive bonding layer. The conductive bonding layer tends to have sheet resistance higher than the transparent electrode film. Therefore, even in a configuration of the display panel having a built-in touch panel pattern, the signals for detecting touching are less likely to be shielded by the conductive bonding layer. The function of the touch panel can be optimally exerted. The multifunction of the display panel is preferably achieved. The conductive member is disposed to overlap the conductive bonding layer on the counter board side. This configuration is preferable for connecting the conductive bonding layer that is disposed within a plate surface area of the polarizing plate to the ground connection member.

Preferable embodiments of the present technology may include the following configurations.

(1) The conductive member may include a polarizing plate overlapping portion that overlaps the polarizing plate and is connected to the conductive bonding layer and a polarizing plate non-overlapping portion that does not overlap the polarizing plate and is connected to the conductive member. According to such a configuration, the conductive bonding layer that is necessarily included within a plate surface of the polarizing plate is connected to the polarizing plate overlapping portion of the conductive member overlapping on the counter board side and the ground connection member is connected to the polarizing plate non-overlapping portion of the conductive member. According to such a configuration, timing of connecting the ground connection member to the conductive member is not necessarily related to timing of bonding the polarizing plate to the counter board. Therefore, the ground connection member can be connected to the conductive member in various ways.

(2) The array board may include a counter board non-overlapping portion that does not overlap the counter board and a ground pad that is connected to ground and disposed on the counter board non-overlapping portion, and the ground connection member may be formed from conductive paste extending from the ground pad to the conductive member. A level difference corresponding to a thickness of the counter board is between the conductive member disposed on the counter board and the ground pad disposed on the counter board non-overlapping portion of the array board. The ground connection member is formed from the conductive paste that can be easily disposed to extend from the ground pad to the conductive member while covering the level difference and high connection reliability can be obtained.

(3) Each of the array board and the counter board may include a display area displaying images and a non-display area surrounding the display area, and the conductive member may be disposed in the non-display area. According to such a configuration, the conductive member is less likely to adversely affect images displayed in the display area. The material that is opaque and excellent in conductivity such as metal can be used as the material of the conductive member and therefore, high connection reliability with the ground connection member can be obtained.

(4) The conductive member may be formed from a conductive tape. According to such a configuration, in comparison to a conductive member formed from a conductive pad that is fixed on a plate surface of the counter board, the conductive member can be deformed freely. Therefore, it is easy to achieve a configuration such that the conductive member extends to a position different from the plate surface of the counter board.

(5) The display panel may further include a second polarizing plate bonded to the array board on a plate surface opposite from the counter board side and including a second conductive bonding layer bonded to the array board. The conductive member may include a first connection portion disposed on the plate surface of the counter board opposite from the array board side and connected to the conductive bonding layer and the ground connection member, an edge surface opposite portion continuous from the first connection portion and opposite edge surfaces of the array board and the counter board, and a second connection portion continuous from the edge surface opposite portion and disposed on the plate surface of the array board opposite from the counter board side and overlapping the second conductive bonding layer on the array board side with respect to the second conductive bonding layer. According to such a configuration, the second polarizing plate bonded to the array board on the plate surface opposite from the counter board side is bonded to the array board via the second conductive bonding layer. The second conductive bonding layer is connected to the second connection portion of the conductive member overlapping the second conductive bonding layer on the array board side. The second connection portion is continuous to the edge surface opposite portion that is opposite the edge surfaces of the array board and the counter board. The edge surface opposite portion is further continuous to the first connection portion that is connected to the conductive bonding layer and the ground connection member. According to such a configuration, the array board is effectively shielded by the second conductive bonding layer. Thus, the conductive bonding layer, the second conductive bonding layer, and the around connection member are connected to one another via the conductive member. The number of components and a cost can be reduced.

(6) The conductive member may be arranged such that the first connection portion and the second connection portion are adjacent to the edge surfaces of the array board and the counter board. According to such a configuration, in comparison to a configuration that the first connection portion and the second connection portion are away from the edge surfaces of the array board and the counter board, the first connection portion and the second connection portion that are continuous from the edge surface opposite portion opposite the edge surfaces of the array board and the counter board can be shortened.

(7) The conductive member may be arranged such that the first connection portion and the second connection portion overlap each other. According to such a configuration, in comparison to a configuration that the first connection portion and the second connection portion do not overlap each other, the edge surface opposite portion that is continuous to the first connection portion and the second connection portion can be shortened.

(8) One of the polarizing plate and the second polarizing plate may include a portion that does not overlap another one of the polarizing plate and the second polarizing plate, and one of the first connection portion and the second connection portion that is connected to one of the conductive bonding layer and the second conductive bonding layer included in the other one of the polarizing plate and the second polarizing plate may include a portion overlapping another one of the first connection portion and the second connection portion that is to be connected to another one of the conductive bonding layer and the second conductive bonding layer included in the one of the polarizing plate and the second polarizing plate and a portion not overlapping the other one of the first connection portion and the second connection portion. Even if the polarizing plate and the second polarizing plate have a different size, the conductive member formed from the conductive tape can freely form the first connection portion and the second connection portion in various areas. The first connection portion and the second connection portion can be effectively connected to the conductive bonding layer and the second conductive bonding layer.

### Advantageous Effect of the Invention

According to the present invention, multifunctionality is achieved.

### BRIEF DESCRIPTION OF THE DRAWINGS

FIG. 1 is a schematic plan view illustrating a connection configuration of a liquid crystal panel, a flexible printed circuit board, and a control circuit board according to a first embodiment of the present invention.

FIG. 2 is a schematic cross-sectional view illustrating a cross-sectional configuration of a display area of a liquid crystal panel.

FIG. 3 is a schematic plan view illustrating a tracing configuration in the display area of an array board included in the liquid crystal panel.

FIG. 4 is a plan view illustrating a planar configuration in the display area of a CF board included in the liquid crystal panel.

FIG. 5 is a cross-sectional view taken along line A-A in FIG. 3.

FIG. 6 is a cross-sectional view taken along line B-B in FIG. 1.

FIG. 7 is a cross-sectional view taken along line B-B in FIG. 1 before the CF board and the array board are bonded to each other.

FIG. 8 is a cross-sectional view taken along line B-B in FIG. 1 before bonding each polarizing plate.

FIG. 9 is a cross-sectional view taken along line B-B in FIG. 1 before forming a ground connection portion.

FIG. 10 is a bottom view of a liquid crystal panel according to a second embodiment of the present invention.

FIG. 11 is a front view of a liquid crystal panel.

FIG. 12 is a cross-sectional view taken along line B-B in FIG. 11.

FIG. 13 is a left side view of the liquid crystal panel.

FIG. 14 is a front view illustrating bonded substrates in a pair before a conductive member is bonded.

FIG. 15 is a cross-sectional view taken along line B-B in FIG. 11 before each polarizing plate is bonded.

FIG. 16 is a cross-sectional view taken along line B-B in FIG. 11 before forming a ground connection portion.

FIG. 17 is a bottom view of a liquid crystal panel according to a third embodiment of the present invention.

FIG. 18 is a side cross-sectional view of the liquid crystal panel.

FIG. 19 is a left side view of the liquid crystal panel.

### MODES FOR CARRYING OUT THE INVENTION

### First Embodiment

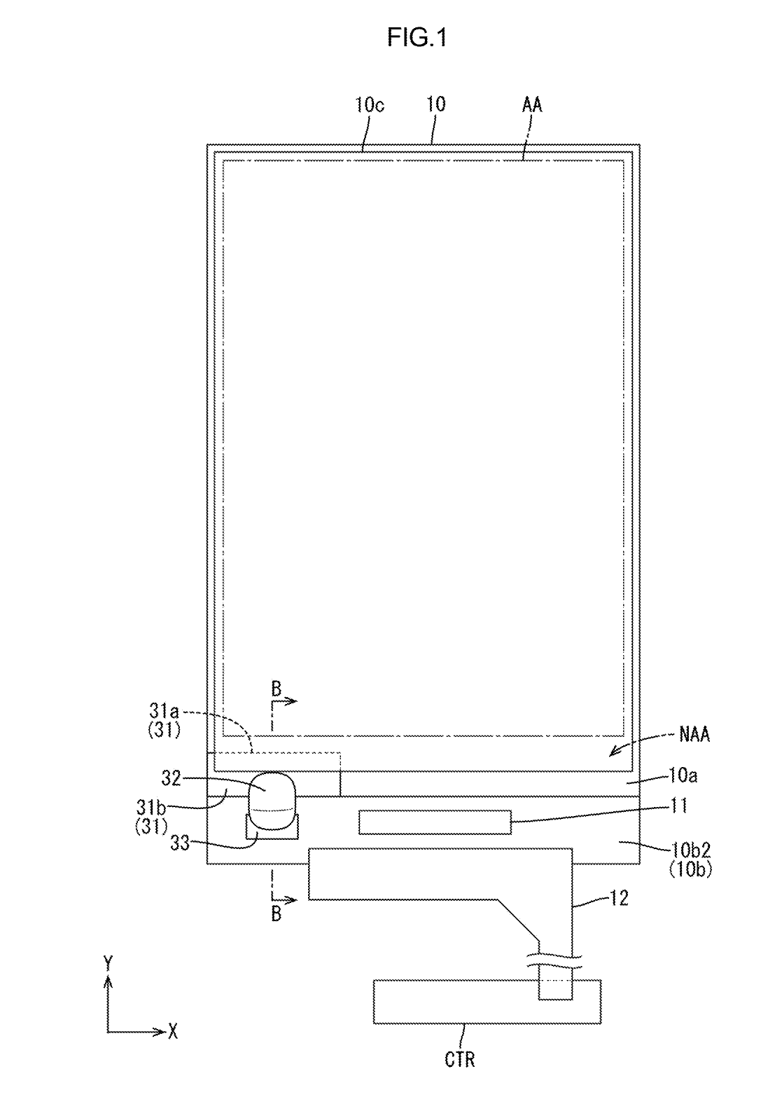

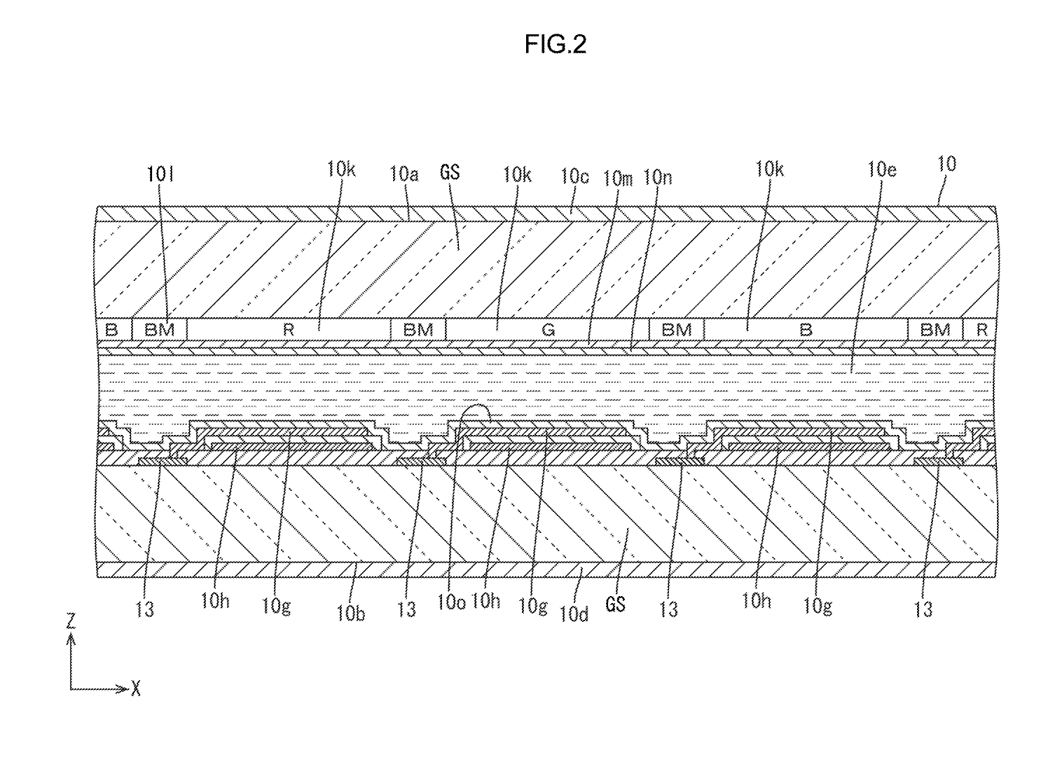

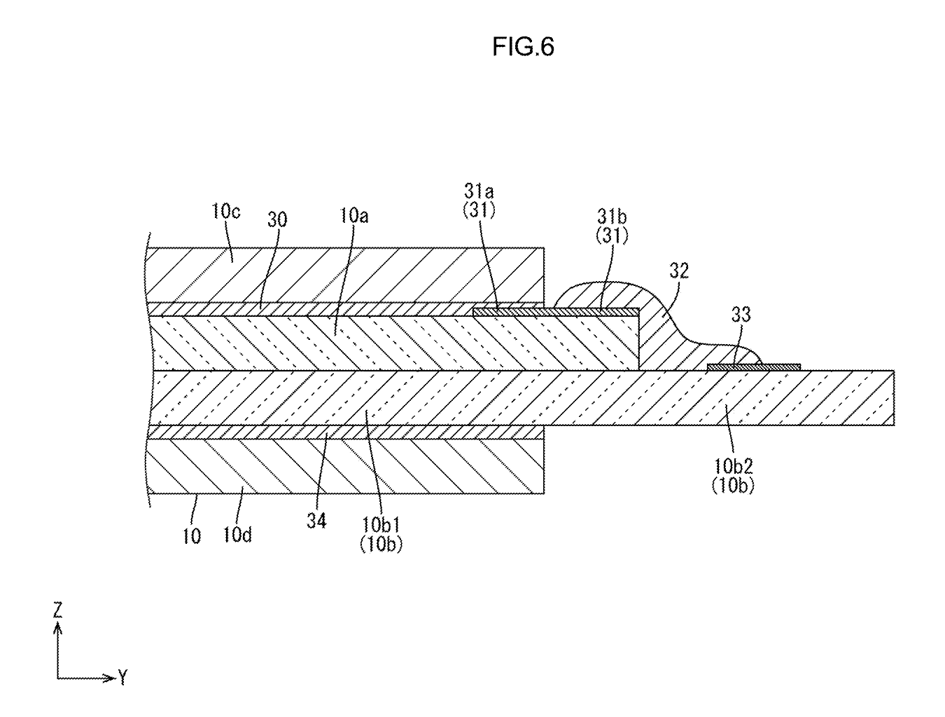

A first embodiment will be described with reference to FIGS. 1 to 9. In the present embodiment, a liquid crystal panel 10 will be described. X-axis, Y-axis and Z-axis may be indicated in the drawings. The axes in each drawing correspond to the respective axes in other drawings. An upper side and a lower side in FIGS. 2 and 6 correspond to a front side and a back side, respectively.

The liquid crystal panel 10 according to this embodiment and a backlight device (a lighting device), which is not illustrated, are included in a liquid crystal display device, and the liquid crystal panel 10 displays images with using light rays supplied from the backlight device. On the liquid crystal panel 10, a driver (a panel driving portion) 11 and a flexible printed circuit board (an external connector) 12 are mounted. Various signals are supplied to the liquid crystal panel 10 via the flexible printed board 12 from a control circuit board (a control board) CTR, which is an external signal supply source. The liquid crystal panel 10 may be used in various kinds of electronic devices (not illustrated) such as mobile phones (including smartphones), notebook computers (including tablet computers), wearable terminals (including smart watches), handheld terminals (including electronic books and FDAs), portable video game players, and digital photo frames. The liquid crystal panel 10 is in a range between some inches to ten and some inches. Namely, the liquid crystal panel 10 is in a size that is classified as a small or a small-to-medium.

As illustrated in FIG. 1, the liquid crystal panel 10 has a horizontally-long rectangular overall shape. The liquid crystal panel 10 includes a display area (an active area) AA that is off centered toward one of short-side ends thereof (the upper side in FIG. 1). The driver 11 and the flexible printed circuit board 12 are arranged at the other one of the short-side ends of the liquid crystal panel 10 (the lower side in FIG. 1). An area of the liquid crystal panel 10 outside the display area AA is a non-display area (non-active area) NAA in which images are not displayed and the non-display area includes a frame-shaped area surrounding the display area AA (a frame portion of a CF board 10a, which will be described later) and an area provided on the other short-side end (a portion of an array board 10b not overlapping the CF board 10a). The area provided on the other short-side end includes a mounting area in which the driver 11 and the flexible printed circuit board 12 are mounted. A short-side direction and a long-side direction of the liquid crystal panel 10 correspond to the X-axis direction and the Y-axis direction in each drawing. In FIG. 1, a chain line box slightly smaller than the CF board 11a indicates a boundary of the display area AA. An area outside the solid line is the non-display area NAA.

As illustrated in FIG. 1, the control circuit board CTR includes a substrate made of paper phenol or glass epoxy resin and electronic components mounted on the substrate for supplying various kinds of input signals to the driver 11. The control circuit board CTR further includes predetermined traces (conductive lines), which are not illustrated, routed on the substrate. One of ends of the flexible printed circuit board 12 is electrically and mechanically connected to the control circuit board CTR via an anisotropic conductive film (ACF), which is not illustrated.

As illustrated in FIG. 1, the flexible printed circuit board 12 includes a base member made of synthetic resin (e.g., polyimide resin) having an insulating property and flexibility. The flexible printed circuit board 12 includes traces (not illustrated) on the base member. The flexible printed circuit board 12 has effective flexibility and a portion of the flexible printed circuit board 12 between an end portion thereof connected to the liquid crystal panel 10 and an end portion thereof connected to the control circuit board CTR can be freely folded within a range of elastic limit.

As illustrated in FIG. 1, the driver 11 includes an LSI chip including a driver circuit therein. The driver 11 operates according to signals supplied by the control circuit board CTR, which is a signal source, process the input signals supplied by the control circuit board CTR, which is a signal source, generates output signals, and sends the output signals to the display area AA of the liquid crystal panel 10. The driver 11 has a horizontally long rectangular shape in the plan view (an elongated shape along a short side of the liquid crystal panel 10). The driver 11 is directly mounted on the array substrate 10b in the non-display area NAA of the liquid crystal panel 10 with the COG (chip on glass) mounting technology. The long-side direction and the short-side direction of the driver 11 correspond to an X-axis direction (a short-side direction of the liquid crystal panel 10) and a Y-axis direction (a long-side direction of the liquid crystal panel 10), respectively.

The liquid crystal panel 10 will be described in detail. As illustrated in FIG. 2, the liquid crystal panel 10 includes a pair of transparent glass substrates (having transmissivity) 10a and 10b, and a liquid crystal layer 10e between the substrates 10a and 10b. The liquid crystal layer 10e includes liquid crystal molecules (liquid crystal material) having optical characteristics that vary according to application of electric field. The substrates 10a and 10b are bonded together with a sealing agent, which is not illustrated, with a gap of a thickness of the liquid crystal layer 10e therebetween. One of the substrates 10a, 10b on the front (on a front surface side) is the CF board (a counter board) 10a and another one on the back side (on a rear surface side) is the array board (an active matrix board, a component board) 10b. As illustrated in FIG. 1, the CF board 10a has a short-side dimension substantially same as that of the array board 10b and has a long-side dimension smaller than that of the array board 10b. The CF board 10a and the array board 10b are bonded together such that short-side edges (upper-side edges in FIG. 1) thereof are aligned with each other. According to such a configuration, the CF board 10a and the array board 10b are not overlapped with each other in the other short-side edge portions thereof (lower-side edges in FIG. 1) over a certain area and the short-side edge portion of the array board 10b is exposed outside on the front and rear plate surfaces thereof. Thus, the exposed portion is a mounting area where the driver 11 and the flexible printed circuit board 12 are mounted. The array board 10b has a CF board overlapping portion (a counter board overlapping portion) 10b1 that overlaps the CF board 10a in the plan view and a CF board non-overlapping portion (a counter board non-overlapping portion) 10b2 that does not overlap the CF board 10a in the plan view and is disposed on a side of the CF board overlapping portion 10b1. The driver 11 and the flexible printed circuit board 12 are mounted on the CF board non-overlapping portion 10b2. Polarizing plates 10c, 10d, which will be described in detail later, are bonded to outer surfaces of the boards 10a, 10b, respectively.

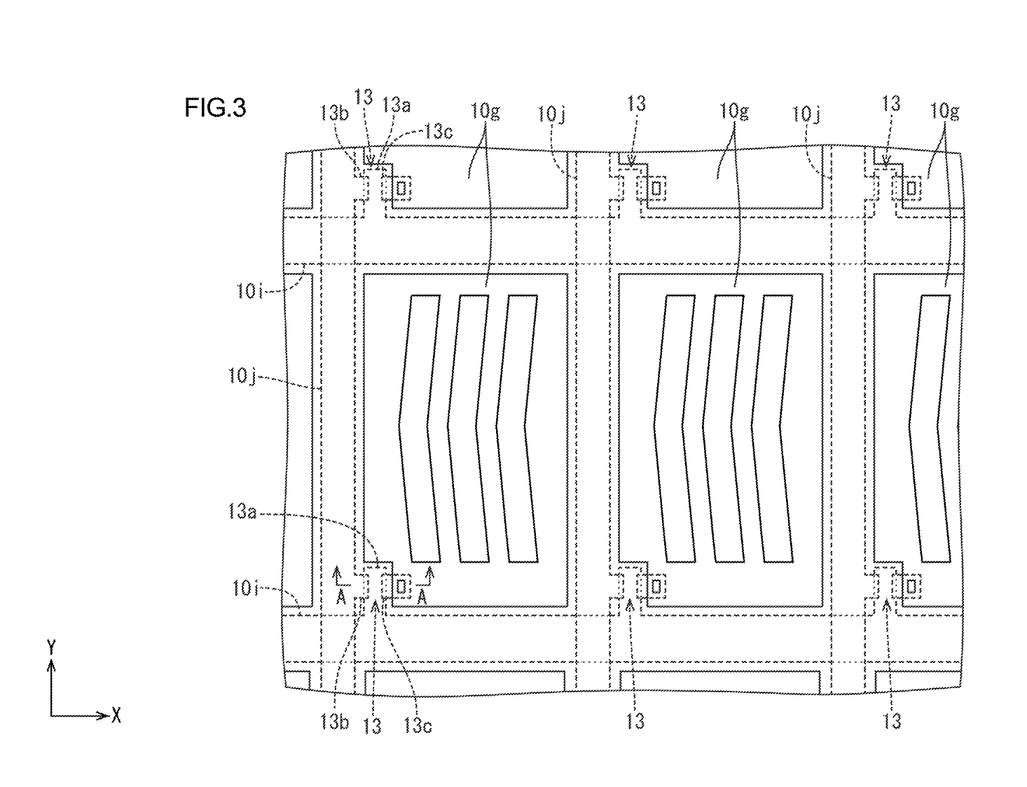

As illustrated in FIGS. 2 and 3, a number of the TFTs (thin film transistors) 13 and a number of pixel electrodes 10g are arranged in a matrix in the display area of the inner surface of the array board 10b (the liquid crystal layer 10e side, the opposed surface side opposed to the CF board 10a). Furthermore, the gate lines (scanning lines) 10i and the source lines (data lines, signal lines) 10j are arranged in a grid to surround the TFTs 13 and the pixel electrodes 10g. The gate lines 10i and the source lines 10j are connected to gate electrodes 13a and source electrodes 13b of the TFTs 13, respectively. The pixel electrodes 10g are connected to drain electrodes 13c of the TFTs 13. The TFTs 13 are driven based on the signals supplied to the gate lines 10i and the source lines 10j and supply of potential to the pixel electrodes 10g is controlled according to the driving. The TFTs 13 include channel portions 13d bridging the drain electrodes 13c and the source electrodes 13b and oxide semiconductor material is used as a semiconductor film of the channel portions 13d. The oxide semiconductor material included in the channel portions 13d has electron mobility higher than that of an amorphous silicon film, for example, 20 to 50 times higher. Therefore, the display area of the TFTs 13 can be easily downsized and an amount of transmitted light through each pixel electrode 10g (an aperture ratio of the display pixel) can be increased to a maximum level. This configuration is preferable for enhancement of image resolution and reduction of power consumption. Each of the pixel electrodes 10g is arranged in each of square areas surrounded by the gate lines 10i and the source lines 10j and are made of transparent electrode film (a second transparent electrode film 28) such as indium tin oxide (ITO) and zinc oxide (ZnO). On the inner surface of the array board 10b in the display area AA, a common electrode 10h is disposed between the array board 10b and the pixel electrodes 10g via an insulation film (a second interlayer insulation film 27). The common electrode 10h is disposed on an upper layer side of the insulation film and is made of the transparent electrode film (a first transparent electrode film 26). The common electrode 10h is formed in a substantially solid pattern. In this embodiment, in each of the drawings, an extending direction of the gate lines 10i matches the X-axis direction and an extending direction of the source lines 10j matches the Y-axis direction.

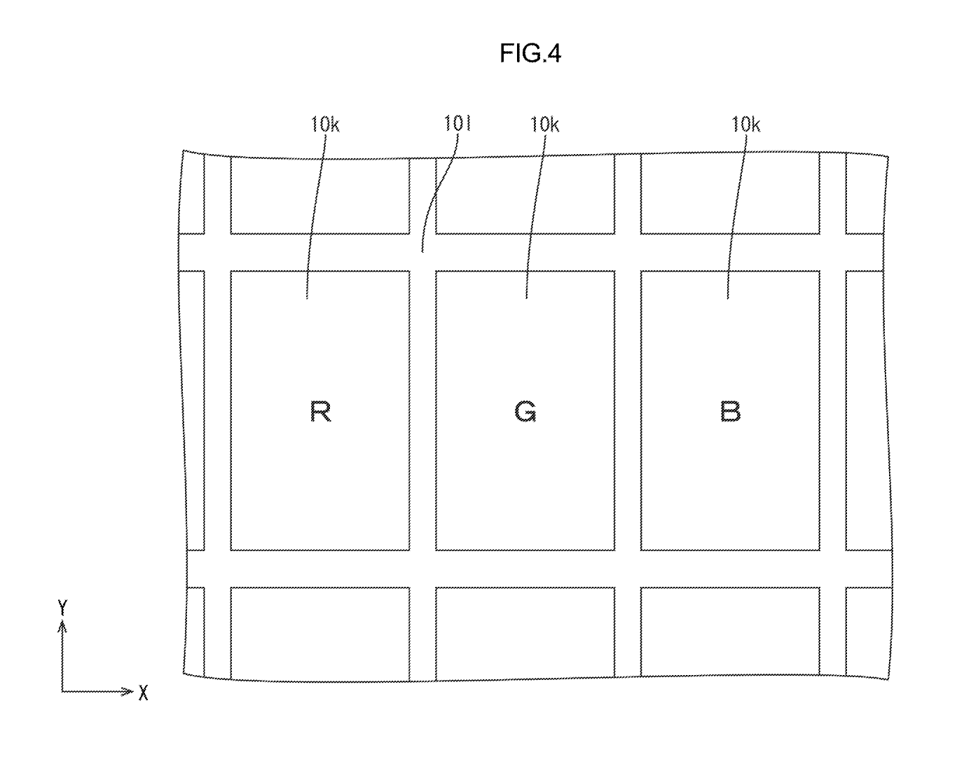

As illustrated in FIGS. 2 and 4, color filters 10k are formed on an inner surface side of the display area AA of the CF substrate 11a. The color filters 10k are arranged in a matrix to be opposite the pixel electrodes 10g on the array substrate 10b side. The color filters 10k include red (R), green (G), and blue (B) color films that are arranged in a predefined sequence repeatedly. A light blocking film 10l having a grid shape (a black matrix) is formed between the color filters 10k for reducing color mixture. The light blocking film 10l is arranged to overlap the gate lines 10i and the source lines 10j in a plan view. An overcoat film 10m is disposed on the color filters 10k and the light blocking film 10l. A photo spacer is disposed on a surface of the overcoat film 10m. Alignment films 10n, 10o that align the liquid crystal molecules contained in the liquid crystal layer 10e are formed on inner surfaces of the respective boards 10a, 10b. In the liquid crystal panel 10, the R (red) color film, the G (green) color film, the B (blue) color film included in the color filters 10k, and three pixel electrodes 10g opposed to the color films form a display pixel that is a display unit. Each display pixel includes a red pixel including the R color filter 10k, a green pixel including the G color filter 10k, and a blue pixel including the B color filter 10k. The color pixels are repeatedly arranged along a row direction (the X-axis direction) on a plate surface of the liquid crystal panel 10 to form lines of display pixels. The lines of display pixels are arranged along the column direction (the Y-axis direction).

In this embodiment, a driving type of the liquid crystal panel 10 is a fringe filed switching (FFS) type that is a mode improved from an in-plane switching (IPS) mode. As illustrated in FIG. 2, the pixel electrodes 10g and the common electrode 10h are formed on the array board 10b side among the boards 10a, 10b and the pixel electrodes 10g and the common electrode 10h are included in different layers. Each of the CF board 10a and the array board 10b includes a substantially transparent glass substrate GS (having high transmissivity) and various films that are formed in layers on the glass substrate GS.

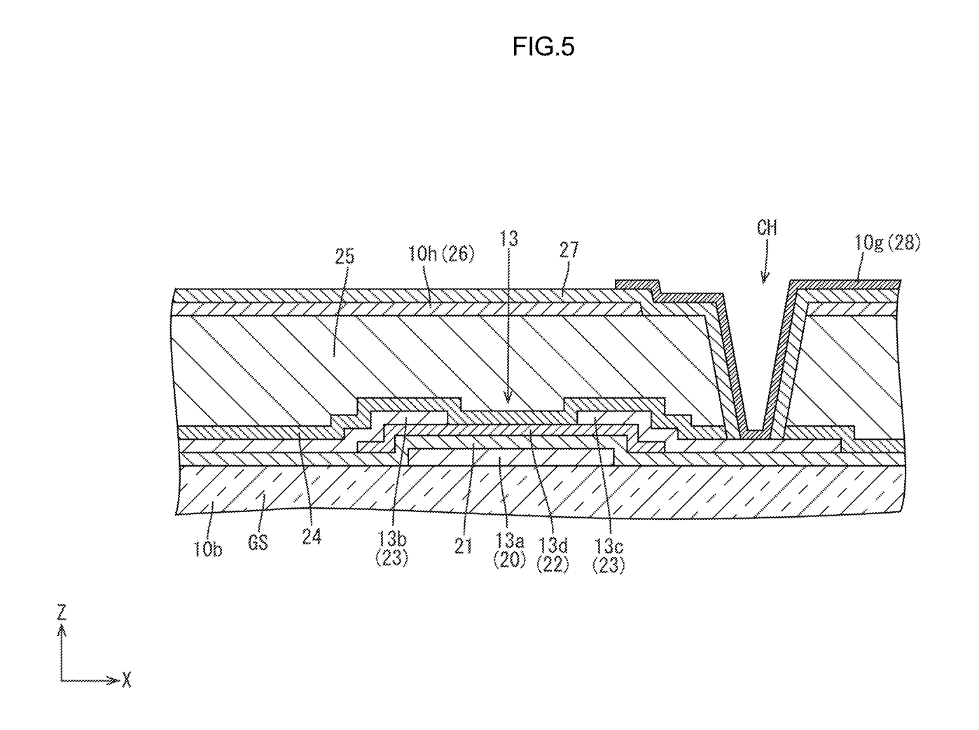

The various films formed in layers on the inner surface side of the array board 10b with the known photolithography method will be described. As illustrated in FIG. 5, on the array board 10b, a first metal film (a gate metal film) 20, a gate insulation film (an insulation film) 21, a semiconductor film 22, a second metal film (a source metal film) 23, a first interlayer insulation film 24, an organic insulation film 25, a first transparent electrode film 26, a second interlayer insulation film 27, a second transparent electrode film 28, and the alignment film 10o are formed in layers.

The first metal film 20 is a layered film of titanium (Ti) and copper (Cu). With such a configuration, the first metal film 20 has lower trace resistance and good conductivity compared to a layered film of titanium and aluminum (Al). The gate insulation film 21 is formed in a layer on an upper layer side of the first metal film 20 and made of silicon oxide (SiO₂) that is inorganic material. The semiconductor film 22 is formed in a layer on an upper layer side of the gate insulation film 21 and is a thin film including oxide semiconductors. Specific oxide semiconductors included in the semiconductor film 22 may include In—Ga—Zn—O semiconductors (indium gallium zinc oxide) containing indium (In), gallium (Ga), and zinc (Zn). The In—Ga—Zn—O semiconductor is ternary oxide of indium (In), gallium (Ga), and zinc (Zn). A ratio (composition ratio) of indium (In), gallium (Ga), and zinc (Zn) is not limited and may be In:Ga:Zn=2:2:1, In:Ga:Zn=1:1:1, or In:Ga:Zn=1:1:2, for example. In this embodiment, the In—Ga—Zn—O semiconductor contains In, Ga, and Zn at a ratio of 1:1:1. The oxide semiconductor (the In—Ga—Zn—O semiconductor) may be amorphous or may be preferably crystalline. The crystalline oxide semiconductor may be preferably a crystalline In—Ga—Zn—O semiconductor having c-axis oriented vertical to a layer surface. A crystalline structure of such an oxide semiconductor (In—Ga—Zn—O semiconductor) is disclosed in JPA 2012-134475, for example. The entire contents of JPA 2012-134475 are incorporated herein by reference.

The second metal film 23 is disposed on an upper layer side of the semiconductor film 22 and is a layered film that contains titanium (Ti) and copper (Cu) similar to the first metal film 20. According to such a configuration, the second metal film 23 has lower trace resistance and good conductivity compared to a layered film of titanium and aluminum (Al). The first interlayer insulation film 24 is formed in a layer at least on an upper layer side of the second metal film 23 and contains silicon oxide (SiO₂), which is an inorganic material. The organic insulation film 25 is formed in a layer on an upper layer side of the first interlayer insulation film 24 and contains acrylic resin (e.g., polymethyl methacrylate (PMMA)), which is an organic material. The first transparent electrode film 26 is formed in a layer on an upper layer side of the organic insulation film 25 and made of transparent electrode material such as indium tin oxide (ITO) and zinc oxide (ZnO). The second interlayer insulation film 27 is formed in a layer at least on an upper layer side of the first transparent electrode film 26 and contains silicon nitride (SiNx), which is an inorganic material. The second transparent electrode film 28 is formed in a layer on an upper layer side of the second interlayer insulation film 27 and made of transparent electrode material such as indium tin oxide (ITO) and zinc oxide (ZnO) similarly to the first transparent electrode film 26. The alignment film 10o is formed in a layer at least on an upper layer side of the second transparent electrode film 28 to be exposed to the liquid crystal layer 10e. Among the insulation films 21, 24, 25, 27, the organic insulation film 25 is thicker than the inorganic insulation films 21, 24, 27 and functions as a planarization film. Among the insulation films 21, 24, 25, 27, the gate insulation film 21, the first interlayer insulation film 24, and the second insulation film 27 other than the organic insulation film 25 are inorganic insulation film containing inorganic material and thinner than the organic insulation film 25.

The TFTs 13, the pixel electrodes 10g, and the common electrode 10h configured by the films will be described in detail. As illustrated in FIG. 5, each TFT 13 includes a gate electrode 13a, a channel 13d, a source electrode 13b, and a drain electrode 13c. The gate electrode is formed from the first metal film 20. The channel 13d is formed from the semiconductor film 22 and arranged so as to overlap the gate electrode 13a in a plan view. The source electrode 13b is formed from the second metal film 23 and connected to one end of the channel 13d. The drain electrode 13c is formed from the second metal film 23 and connected to another end of the channel 13d. The channel 13d extends in the X-axis direction and bridges the source electrode 13b and the drain electrode 13c so that electrons move between the electrodes 13b and 13c. The source electrode 13b and the drain electrode 13c are opposite at a predefined distance therebetween in the extending direction of the channel 13d (the X-axis direction).

As illustrated in FIG. 3, each pixel electrode 10g is formed from the second transparent electrode film 28. The pixel electrode 10g has a vertically-long rectangular overall shape in a plan view and arranged in an area defined by the gate lines 10i and the source lines 10j. The pixel electrode 10g includes longitudinal slits which form a comb-shaped portion. As illustrated in FIG. 5, the pixel electrode 10g is formed on the second interlayer insulation film 27. The second interlayer insulation film 27 is between the pixel electrode 10g and the common electrode 10h, which will be described later. A contact hole CH is formed through portions of the first interlayer insulation film 24, the organic insulation film 25, and the second interlayer insulation film 27 that are disposed under the pixel electrode 10g. The contact hole CH that is a through hole is formed at the portions of the films that overlap the drain electrode 13c in a plan view. The pixel electrode 10g is connected to the drain electrode 13c via the contact hole CH. When a voltage is applied to the gate electrode 13a of the TFT 13, electrical conduction via the channel 13d occurs between the source electrode 13b and the drain electrode 13c. As a result, a predetermined potential is applied to the pixel electrode 10g. The contact hole CH is formed not to overlap the gate electrode 13a and the channel 13d formed from the semiconductor film 22 in a plan view.

The common electrode 10h is formed from the first transparent electrode film 26 and is between the organic insulation film 25 and the second interlayer insulation film 27 as illustrated in FIG. 5. A common potential (a reference potential) is applied to the common electrode 10h through a common line, which is not illustrated. By controlling the potential applied to the pixel electrode 10a by the TFT 13 as described above, a predetermined potential difference occurs between the electrodes 10g and 10h. When a potential difference appears between the electrodes 10g and 10h, a fringe field (an oblique field) including a component in a direction normal to a plate surface of the array board 10b is applied to the liquid crystal layer 10e in addition to a component in a direction along the plate surface of the array board 10b because of the slits of the pixel electrode 10g. Therefore, not only alignment of the liquid crystal molecules in the slits in the liquid crystal layer 10e but also alignment of the liquid crystal molecules on the pixel electrode 10a is properly switchable. With this configuration, the aperture ratio of a liquid crystal panel 10 improves and a sufficient amount of transmitted light is achieved. Furthermore, high view-angle performance is achieved.

The liquid crystal panel 10 of this embodiment is driven in the FFS mode that is a lateral electric field control mode. The pixel electrode 10g and the common electrode 10h that applies an electric field to the liquid crystal layer 10e are disposed on the array board 10b side and are not disposed on the CF board 10a side. Therefore, in comparison to the array board 10b, the CF board 10a is likely to be charged on a surface thereof and static electricity is likely to remain on the CF board 10a. A vertical electric field may be generated due to the static electricity and an electric field in the liquid crystal layer 10e may be disturbed. Thus, a display error may be caused. In a known liquid crystal panel, a transparent electrode film is formed between the CF board and a polarizing plate and connected to ground as a static electricity countermeasure method. However, in a configuration of a built-in touch panel pattern (in-cell type) for achieving multifunction of the liquid crystal panel 10, touch signals for detecting touching may be shielded by the transparent electrode film. Accordingly, sensitivity of touching may be lowered and functions of the touch panel may not be appropriately exerted.

In this embodiment, as illustrated in FIG. 6, a first polarizing plate (a polarizing plate) 10c is bonded to an outer surface of the CF board 10a, which is a plate surface opposite from an array board 10b side surface, and the first polarizing plate 10c includes a conductive bonding layer 30 that is bonded to the CF board 10a and connected to ground. The conductive bonding layer 30 is connected to around via a conductive member 31 disposed on the CF board 10a, a ground connection member 32 extending between the CF board 10a and the array board 10b, and a ground pad 33 disposed on the array board 10b. The CF board 10a is properly shielded by the conductive bonding layer 30 such that a surface of the CF board 10a is less likely to be charged and static electricity is less likely to remain and display errors is less likely to be caused by the static electricity. The conductive bonding layer 30 tends to have sheet resistance higher than the transparent electrode film. Therefore, even in a configuration of the liquid crystal panel 10 having a built-in touch panel pattern, the touch signals for detecting touching are less likely to be shielded by the conductive bonding layer 30. The function of the touch panel can be optimally exerted. The multifunction of the liquid crystal panel 10 is preferably achieved.

The polarizing plates 10c, 10d will be described in detail. As illustrated in FIG. 6, the polarizing plates 10c, 10d in a pair include the first polarizing plate 10c on an outer surface of the CF board 10a and the second polarizing plate (a second polarizing plate) 10d on an outer surface of the array board 10b. The conductive bonding layer 30 is disposed on a bonding surface of the first polarizing pale 10c that is to be bonded to the CF board 10a and a non-conductive bonding layer 34 is disposed on a bonding surface of the second polarizing plate 10d that is to be bonded to the array substrate 10b. The conductive bonding layer 30 includes glue or adhesive containing conductive particles (antistatic agent) such as conductive fillers. The conductive bonding layer 30 has sheet resistance that is higher than sheet resistance (about 10̂3(10³)Ω/□) of the transparent electrode film made of ITO and may be about 10̂8(10⁸)Ω/□. The values of the sheet resistance of the conductive bonding layer 30 can be controlled easily by adjusting the content (density) of the conductive particles. Therefore, the sheet resistance of the conductive bonding layer 30 can be easily adjusted to be higher than the sheet resistance of the transparent electrode film as described before. Accordingly, in the liquid crystal panel 10 including the built-in touch panel pattern, the touch signals are less likely to be adversely affected and sensitivity of touching is good. The non-conductive bonding layer 34 is made of glue or adhesive and does not contain conductive particles such as the conductive fillers.

As illustrated in FIG. 1, each of the polarizing plates 10c, 10d has a vertically elongated rectangular shape in a plan view similar to each of the boards 10a, 10b and has a same long-side dimension and a same short-side dimension. However, the long-side dimension and the short-side dimension of the polarizing plates 10c, 10d are smaller than the respective dimensions of the CF board 10a and the array substrate 10g. The display area AA is included in each of the polarizing plates 10c, 10d closer to an upper side in FIG. 1. Namely, each of the polarizing plates 10c, 10d includes a frame portion that is the non-display area NAA. A lower side portion of the frame portion near the CF board non-overlapping portion 10b2 is wider than other side portions. The conductive member 31 is disposed such that a part thereof overlaps the wide lower side portion of the first polarizing plate 10c in the non-display area NAA.

The conductive member 31 is formed from a conductive tape including a metal foil such as a copper foil and a conductive bonding agent coated thereon. As illustrated in FIG. 1, the conductive member 31 is arranged at a corner section of the CF board non-overlapping portion 10b2 of the array board 10b in the non-display area NAA of the CF board 10a. The conductive member 31 has a horizontally longitudinal rectangular shape in a plan view. The conductive member 31 is disposed such that a part thereof overlaps the first polarizing plate 10c. The conductive member 31 includes a first polarizing plate overlapping portion 31a overlapping the first polarizing plate 10c and a first polarizing non-overlapping portion 31b not overlapping the first polarizing plate 10c. The first polarizing plate overlapping portion 31a is electrically connected to the conductive bonding layer 30 of the first polarizing plate 10c. As illustrated in FIG. 6, the conductive member 31 is disposed directly on an outer surface of the CF board 10a and the first polarizing plate overlapping portion 31a overlaps the conductive bonding layer 30 on the CF board 10a side. This configuration is preferable for connecting the conductive bonding layer 30 that is disposed within a plate surface area of the first polarizing plate 10c to the ground connection member 32, which will be described later. The first polarizing non-overlapping portion 31b is electrically connected to the ground connection member 32. The first polarizing plate non-overlapping portion 31b is disposed on a section of the CF board 10a that does not overlap the first polarizing plate 10c such that an end surface thereof is flush with a right side edge surface of the CF board 10a in FIG. 6 (a lower side in FIG. 1), or an edge surface on the CF board non-overlapping portion 10b2 side (on a ground pad 33 side).

The ground connection member 32 is made of conductive paste such as silver paste. As illustrated in FIGS. 1 and 6, the ground connection member 32 extends from the first polarizing plate non-overlapping portion 31b of the conductive member 31 to the ground pad 33 and electrically connects them. The conductive member 31 is disposed on the outer surface of the CF board 10a, and the ground pad 33 is disposed on the inner surface of the array board 10b (the CF board non-overlapping portion 10b2). Therefore, a level difference corresponding to a thickness of the CF board 10a is between the conductive member 31 and the ground pad 33. The ground connection member 32 is formed from the conductive paste that can be freely deformed to have a desired shape. Therefore, the ground connection member 32 can be easily disposed to extend from the ground pad 33 to the first polarizing plate non-overlapping portion 31b of the conductive member 31 while covering the level difference and high connection reliability can be obtained. The ground connection member 32 is connected to the first polarizing plate non-overlapping portion 31b of the conductive member 31, and the conductive bonding layer 30 that is necessarily included within a plate surface of the first polarizing plate 10c is connected to the first polarizing plate overlapping portion 31a of the conductive member 31 overlapping on the CF board 10a side. According to such a configuration, timing of connecting the ground connection member 32 to the conductive member 31 is not necessarily related to timing of bonding the first polarizing plate 10c to the CF board 10a. Therefore, the ground connection member 32 can be freely connected to the conductive member 31. The ground connection member 32 does not overlap the first polarizing plate 10c.

As illustrated in FIGS. 1 and 6, the ground pad 33 is disposed on the inner surface (a plate surface opposite from a second polarizing plate 10d side) of the CF board non-overlapping portion 10b2 of the array board 10b and is formed from any of the first metal film 20, the second metal film 23, the first transparent electrode film 26, and the second transparent electrode film 28. Therefore, in a process of producing the array board 10b, the ground pad 33 is formed on the array board 10b by patterning at the same time of forming any of the first metal film 20, the second metal film 23, the first transparent electrode film 26, and the second transparent electrode film 28 by patterning. The ground pad 33 is connected to the driver 11 via the traces (not illustrated) formed on the CF board non-overlapping portion 10b2 of the array board 10b and is connected to ground via the driver 11. The ground connection member 32 overlaps a part of the ground pad 33 on the CF board side 10a to establish connection therebetween.

The liquid crystal panel 10 according to this embodiment has the above-described structure and a method of producing such a liquid crystal panel 10 will be described. The method of producing the liquid crystal panel 10 at least includes a CF board producing process, an array board producing process, a board bonding process, a conductive member mounting process (a conductive member forming process), and a ground connection member disposing process (a ground connection member forming process). The CF board 10a is produced in the CF board producing process, and the array board 10b is produced in the array board producing process. The CF board 10a and the array board 10b are bonded to each other while having the liquid crystal layer 10e therebetween in the board bonding process. The conductive member is mounted in the conductive member mounting process. The polarizing plates 10c, 10d are bonded to the outer surfaces of the boards 10a, 10b, respectively, in the polarizing plate bonding process. The ground connection member 32 is disposed in the ground connection member disposing process. Other than the above processes, the method of producing the liquid crystal panel 10 at least includes a driver mounting process of mounting the driver 11 on the array board 10b, and a flexible circuit board mounting process of mounting a flexible circuit board 12 on the array board 10b.

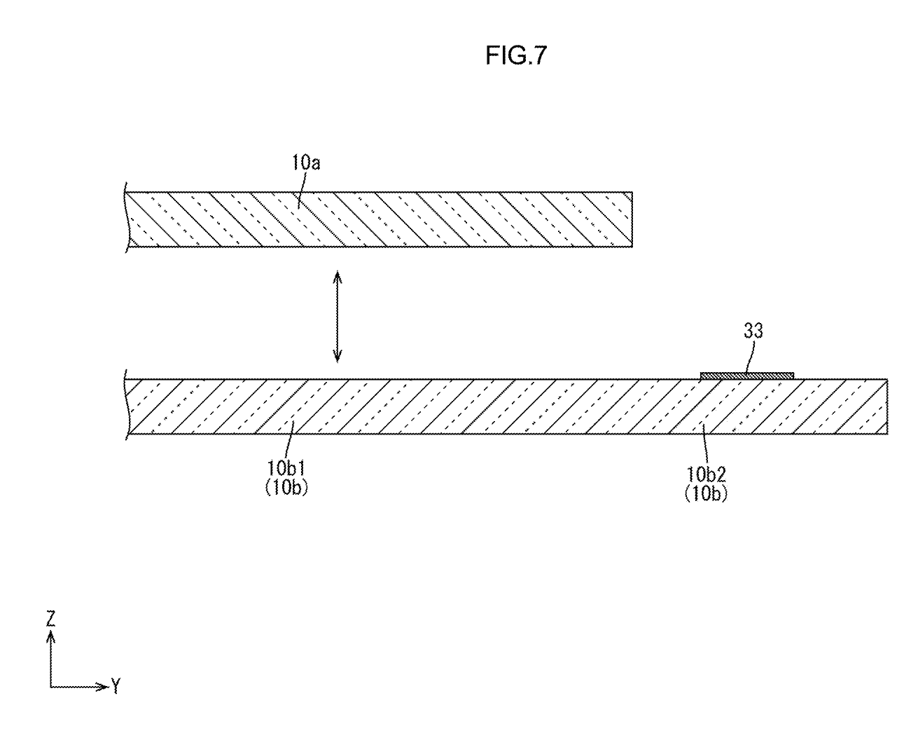

In the CF board producing process and the array board producing process, the various films are formed on the glass substrates GS with the known photolithography method and patterned to form the constructions sequentially. In the array board producing process, the ground pad 33 is patterned on the array board 10b at the same time of pattering any of the first metal film 20, the second metal film 23, the first transparent electrode film 26, and the second transparent electrode film 28 (see FIG. 7). In the board bonding process, in a state illustrated in FIG. 7, sealant is disposed on one of the substrates 10a, 10b and liquid crystal material is dropped on a plate surface of one of the substrates 10a, 10b with a so-called drop injection method. Then, the other one of the substrate 10a, 10b is bonded to the one substrate and the sealant is cured.

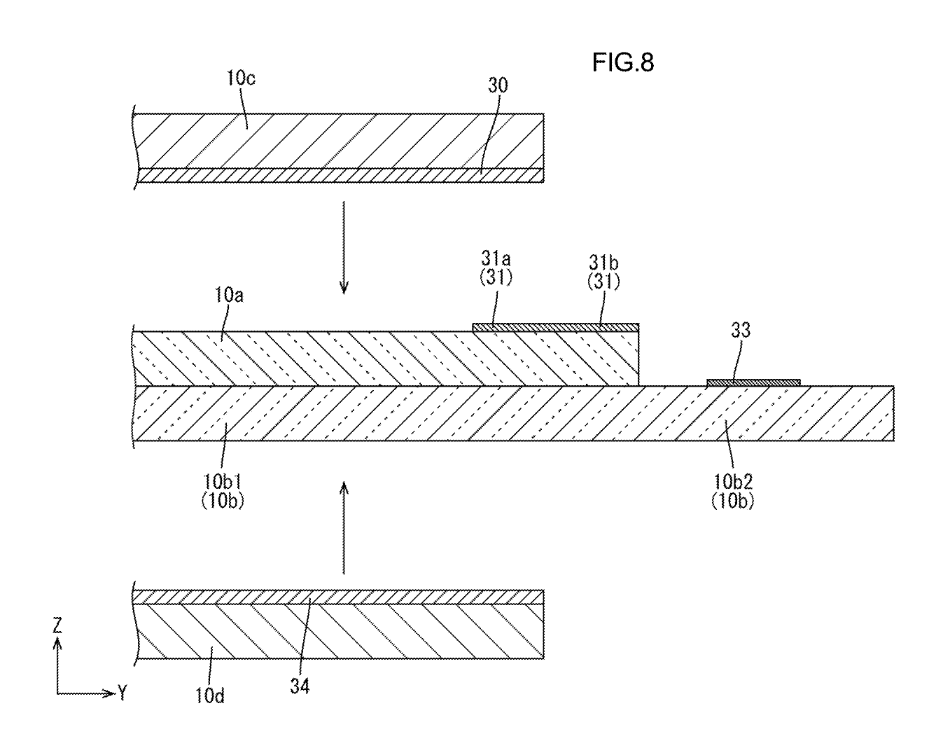

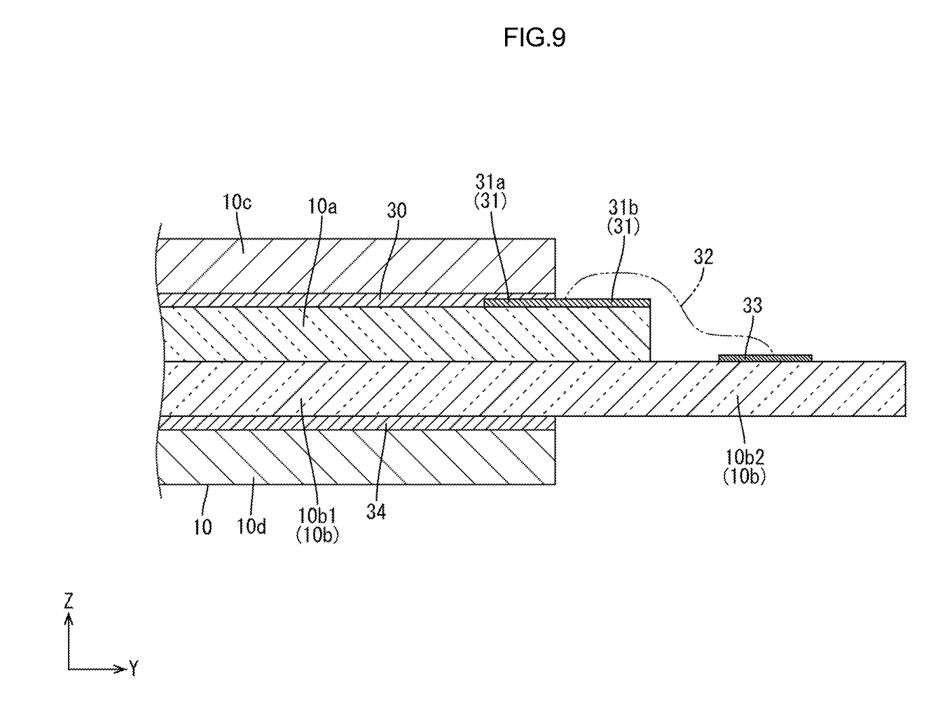

As illustrated in FIG. 8, in the conductive member mounting process, the conductive tape, which is to be the conductive member 31, is disposed on the outer surface of the CF board 10a that is bonded to the array board 10b. The conductive member 31 is arranged to extend from a section of the CF board 10a in the non-display area NAA where the first polarizing plate 10c is to be bonded to a portion of the CF board 10a outside the section. In the polarizing plate bonding process that is performed next, the first polarizing plate 10c and the second polarizing plate 10d are bonded to the outer surfaces of the CF board 10a and the array board 10b, respectively, from the state illustrated in FIG. 8. After the first polarizing plate 10c is bonded to the outer surface of the CF board 10a, as illustrated in FIG. 9, a part of the conductive bonding layer 30 overlaps the first polarizing overlapping portion 31a of the conductive member 31 on the outer side (the first polarizing plate 10c side) and a rest of the conductive bonding layer 30 directly overlaps the outer surface of the CF board 10a. Accordingly, the conductive bonding layer 30 and the conductive member 31 are electrically connected to each other.

In the around connection member disposing process, in the state illustrated in FIG. 9, the conductive paste, which is to be the ground connection member 32, is disposed with coating on an area ranging from the first polarizing plate non-overlapping portion 31b of the conductive member 31 disposed on the outer surface of the CF board 10a to the ground pad 33 disposed on the inner surface of the CF board non-overlapping portion 10b2 of the array board 10b and the disposed conductive paste is cured. Accordingly, as illustrated in FIG. 6, the conductive member 31 and the ground pad 33 are electrically connected to each other via the around connection member 32. The conductive bonding layer 30 is connected to ground via the conductive member 31, the ground connection member 32, and the ground pad 33. According to such a configuration, the surface of the CF board 10a is less likely to be charged and static electricity is less likely to remain on the CF board 10a. Therefore, display errors are less likely to be caused due to the static electricity. The conductive bonding layer 30 has sheet resistance that is effectively higher than the sheet resistance of the transparent electrode film. Therefore, in the liquid crystal panel including a built-in touch panel pattern, the touch signals for detecting touching are less likely to be shielded by the conductive bonding layer 30 and the function of the touch panel can be optimally exerted. It is preferable for achieving the multifunctional liquid crystal panel 10.

As is described before, according to this embodiment, the liquid crystal panel (a display panel) 10 includes the array board 10b, the CF board (a counter board) 10a, the first polarizing plate 10c, a conductive member 31, and the ground connection member 32. The TFTs (display components) 13 are arranged in a matrix on the array board 10b. The CF board 10a is bonded to the array board 10b to be opposite each other. The first polarizing plate 10c is bonded to the plate surface of the CF board 10a opposite from the array board 10b side and includes the conductive bonding layer 30 that is to be bonded to the CF board 10a. The conductive member 31 is disposed on the plate surface of the CF board 10a opposite from the array board 10b side and overlaps the conductive bonding layer 30 on the CF board 10a side. One end of the ground connection member 32 is connected to the conductive member 31 and the other end of the ground connection member 32 is connected to around.

According to such a configuration, the first polarizing plate 10c that is bonded to the plate surface of the CF board 10a opposite from the array board 10b side is bonded to the CF board 10a via the conductive bonding layer 30. The conductive member 31 that is to be overlapped on the CF board 10a side is connected to the conductive bonding layer 30. The conductive member 31 is connected to one end of the ground connection member 32. The other end of the ground connection member 32 is connected to ground. Therefore, static electricity is likely to remain in comparison to the array board 10b, and the CF board 10a that is likely to be adversely affected by the static electricity is properly shielded by the conductive bonding layer 30. The conductive bonding layer 30 tends to have sheet resistance higher than the transparent electrode film. Therefore, even in a configuration of the liquid crystal panel 10 having a built-in touch panel pattern, the signals for detecting touching are less likely to be shielded by the conductive bonding layer 30. The function of the touch panel can be optimally exerted. The multifunction of the liquid crystal panel 10 is preferably achieved. The conductive member 31 is disposed to overlap the conductive bonding layer 30 on the CF board 10a side. This configuration is preferable for connecting the conductive bonding layer 30 that is disposed within a plate surface area of the first polarizing plate 10c to the ground connection member 32.

The conductive member 31 includes the first polarizing plate overlapping portion (a polarizing plate overlapping portion) 31a that overlaps the first polarizing plate 10c and is connected to the conductive bonding layer 30 and the first polarizing non-overlapping portion (a polarizing plate non-overlapping portion) 31b that does not overlap the first polarizing plate 10c and is connected to the conductive member 31. According to such a configuration, the conductive bonding layer 30 that is necessarily included within a plate surface of the first polarizing plate 10c is connected to the first polarizing plate overlapping portion 31a of the conductive member 31 overlapping on the CF board 10a side and the ground connection member 32 is connected to the first polarizing plate non-overlapping portion 31b of the conductive member 31. According to such a configuration, timing of connecting the ground connection member 32 to the conductive member 31 is not necessarily related to timing of bonding the first polarizing plate 10c to the CF board 10a. Therefore, the ground connection member 32 can be connected to the conductive member 31 in various ways.

The array board 10b includes the CF board non-overlapping portion (a counter board non-overlapping portion) 10b2 that does not overlap the CF board 10a. The ground pad 33 that is connected to ground is disposed on the CF board non-overlapping portion 10b2. The ground connection member 32 is formed from the conductive paste that extends from the ground pad 33 to the conductive member 31. A level difference corresponding to a thickness of the CF board 10a is between the conductive member 31 disposed on the CF board 10a and the ground pad 33 disposed on the CF board non-overlapping portion 10b2 of the array board 10b. The ground connection member 32 is formed from the conductive paste that can be easily disposed to extend from the ground pad 33 to the conductive member 31 while covering the level difference and high connection reliability can be obtained.

Each of the array board 10b and the CF board 10a is defined into the display area AA displaying images and the non-display area NAA surrounding the display area AA. The conductive member 31 is arranged in the non-display area NAA. According to such a configuration, the conductive member 31 is less likely to adversely affect images displayed in the display area P.A. The material that is opaque and excellent in conductivity such as metal can be used as the material of the conductive member 31 and therefore, high connection reliability with the ground connection member 32 can be obtained.

The conductive member 31 is formed from a conductive tape. According to such a configuration, in comparison to a conductive member formed from a conductive pad that is fixed on a plate surface of the CF board 10a, the conductive member 31 can be deformed freely. Therefore, it is easy to achieve a configuration such that the conductive member extends to a position different from the plate surface of the CF board 10a.

### Second Embodiment

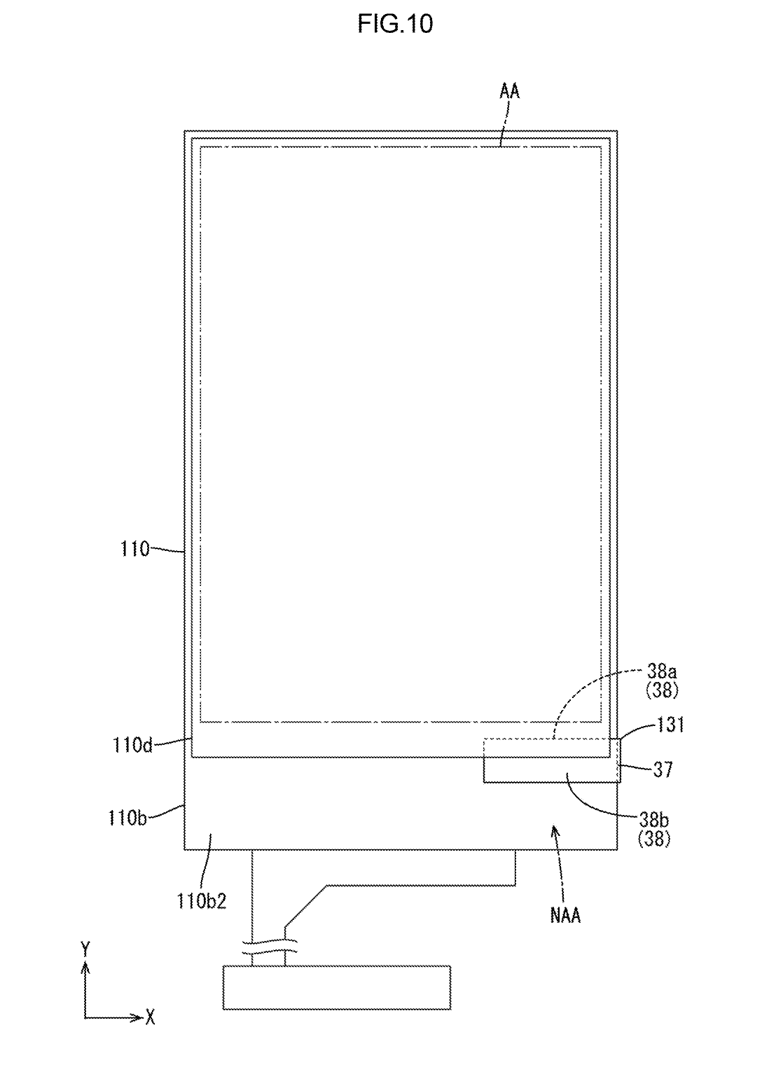

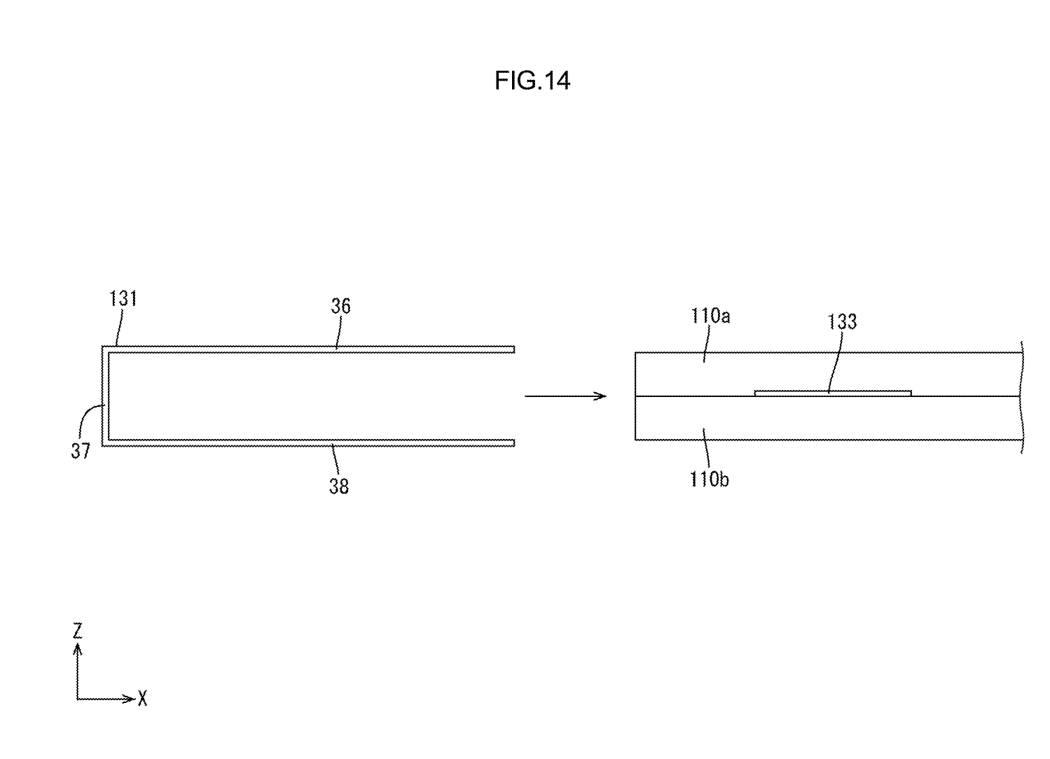

A second embodiment of the present technology will be described with reference to FIGS. 10 to 16. In the second embodiment, a second polarizing plate 110d and a conductive member 131 have configurations that are modified from those of the first embodiment. Configurations, operations, and effects that are similar to those of the first embodiment will not be described.

As illustrated in FIGS. 10 to 13, the second polarizing plate (the second polarizing plate) 110d includes a second conductive bonding layer 35 that is to be bonded to an array board 110b. The second conductive bonding layer 35 includes glue or adhesive containing conductive particles (antistatic agent) such as conductive fillers and has the same configuration as a conductive bonding layer 130. The second conductive bonding layer 35 has sheet resistance that is higher than sheet resistance (about 10̂3(10³)Ω/□) of the transparent electrode film made of ITO and may be about 10̂8(10⁸)Ω/□. The conductive member 131 is connected to the conductive bonding layer 130 of a first polarizing plate 110c, the second conductive bonding layer of the second polarizing plate 110d, and a ground connection member 132 such that the conductive bonding layer 130 and the second conductive bonding layer 35 are connected to ground.

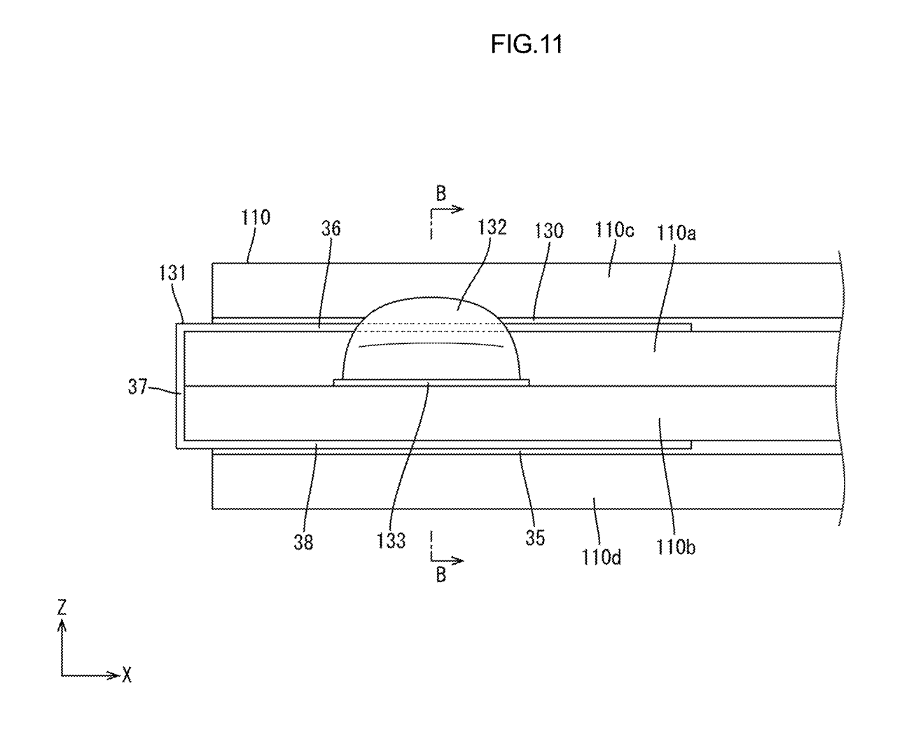

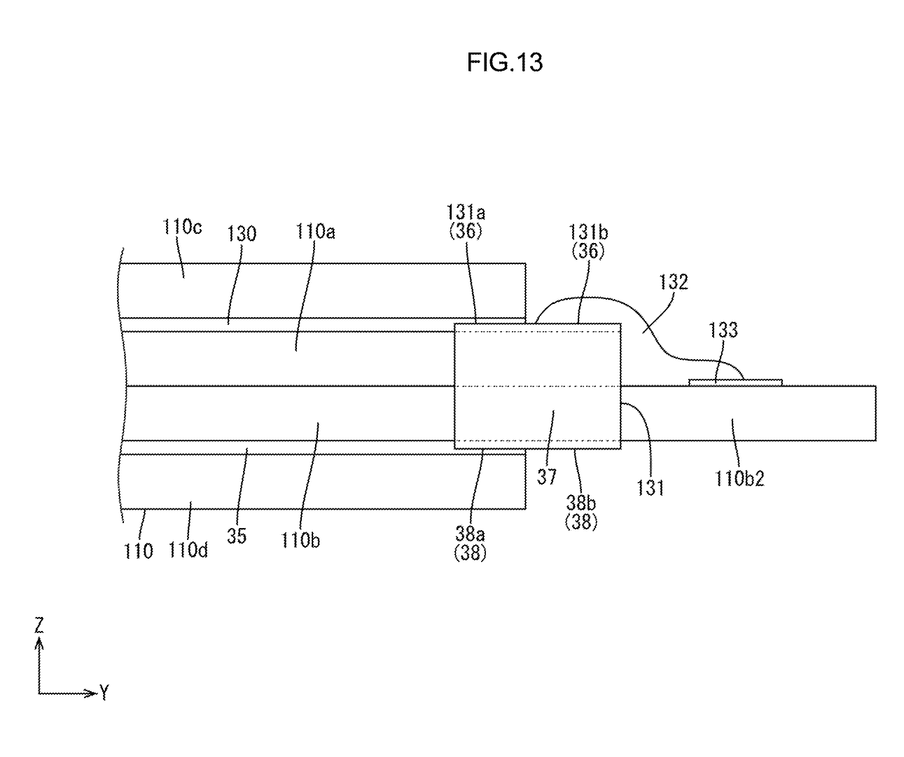

As illustrated in FIGS. 11 and 13, the conductive member 131 includes a first connection portion 36, an edge surface opposite portion 37, and a second connection portion 38. The first connection portion 36 is connected to the conductive bonding layer 130 of first polarizing plate 110c and the ground member 132.

The edge surface opposite portion 37 is continuously from the first connection portion 36 and opposite the edge surfaces of the CF board 110a and the array board 110b. The second connection portion 38 is continuously from the edge surface opposite portion 37 and connected to the second conductive bonding layer 35. Namely, the conductive member 131 has a folded shape like a substantially U-shape as a whole and the first connection portion 36 and the second connection portion 38 sandwich the boards 110a, 110b therebetween from the front and rear sides.

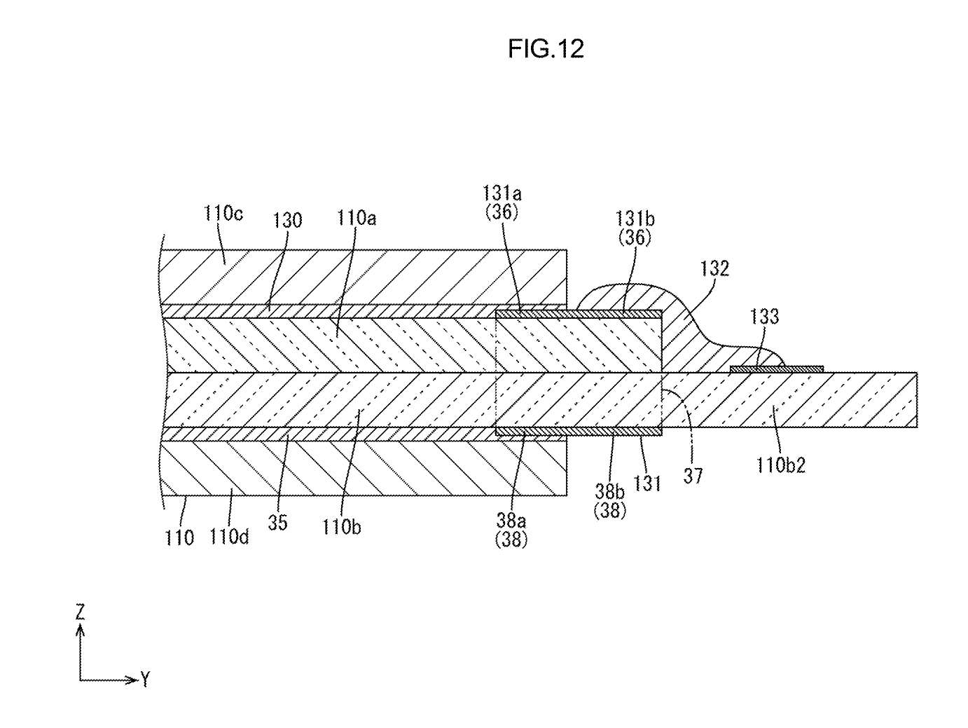

Specifically, as illustrated in FIGS. 11 and 12, the first connection portion 36 is disposed on an outer surface of the CF board 110a and includes a first polarizing plate overlapping portion 131a and a first polarizing plate non-overlapping portion 131b. The first polarizing plate overlapping portion 131a overlaps the first polarizing plate 110c and is connected to the conductive bonding layer 130. The first polarizing plate non-overlapping portion 131b does not overlap the first polarizing plate 110c and is connected to the ground connection member 132. As illustrated in FIGS. 10 to 12, the second connection portion 38 is disposed on an outer surface of the array board 110b (on a plate surface opposite from the CF board 110a side) and includes a second polarizing plate overlapping portion 38a and a second polarizing plate non-overlapping portion 38b. The second polarizing plate overlapping portion 38a overlaps the second polarizing plate 110d and is connected to the second conductive bonding layer 35. The second polarizing plate non-overlapping portion 38b does not overlap the second polarizing plate 110d and is continuous from the edge surface opposite portion 37. The second polarizing plate overlapping portion 38a is disposed to overlap the second conductive bonding layer 35 on the array board 110b side. As illustrated in FIGS. 11 and 13, the edge surface opposite portion 37 is continuous from an edge portion of the first polarizing plate non-overlapping portion 131b of the first connection portion 36, and the edge portion is opposite a long-side edge surface of the CF board 110a, and the edge surface opposite portion 37 is also continuous from an edge portion of the second polarizing plate non-overlapping portion 38b of the second connection portion 38, and the edge portion is opposite a long-side edge surface of the array board 110b. The edge surface opposite portion 37 is in contact or close to edge surfaces of the array board 110b and the CF board 110a. In FIG. 12, the edge surface opposite portion 37 is illustrated with a two-dot chain line in FIG. 12.

According to such a configuration, as illustrated in FIGS. 11 and 12, the second conductive bonding layer 35 is connected to the second connection portion 38 of the conductive member 131 overlapping the second conductive bonding layer 35 on the array board 110b side. The second connection portion 38 is continuous to the edge surface opposite portion 37 that is opposite the edge surfaces of the array board 110b and the CF board 110a. The edge surface opposite portion 37 is further continuous to the first connection portion 36 that is connected to the conductive bonding layer 130 and the ground connection member 132. According to such a configuration, the array board 110b is effectively shielded by the second conductive bonding layer 35. Thus, the conductive bonding layer 130, the second conductive bonding layer 35, and the ground connection member 132 are connected to one another via the conductive member 131. The number of components and a cost can be reduced.

As illustrated in FIGS. 10 and 11, the first connection portion 36 and the second connection portion 38 of the conductive member 131 are adjacent to the edge surfaces of the array board 110b and the CF board 110a. According to such a configuration, in comparison to a configuration that the first connection portion and the second connection portion are away from the edge surfaces of the array board 110b and the CF board 110a, the first connection portion 36 and the second connection portion 38 that are continuous from the edge surface opposite portion 37 opposite the edge surfaces of the array board 110b and the CF board 110a can be shortened. The conductive member 131 is arranged such that the first connection portion 36 overlaps the second connection portion 38. According to such a configuration, in comparison to a configuration that the first connection portion and the second connection portion do not overlap each other, the edge surface opposite portion 37 that is continuous to the first connection portion 36 and the second connection portion 38 can be shortened. Thus, the first connection portion 36 and the second connection portion 38 are appropriately arranged such that a whole size (a whole area) of the conductive member 131 can be smallest and a cost for the conductive member 131 can be reduced. An entire area of the second connection portion 38 overlaps the first connection portion 36 (the first polarizing plate overlapping portion 131a and the first polarizing plate non-overlapping portion 131b). Therefore, similarly to the first connection portion 36, the second connection portion 38 overlaps the non-display area NAA and does not overlap the display area AA.

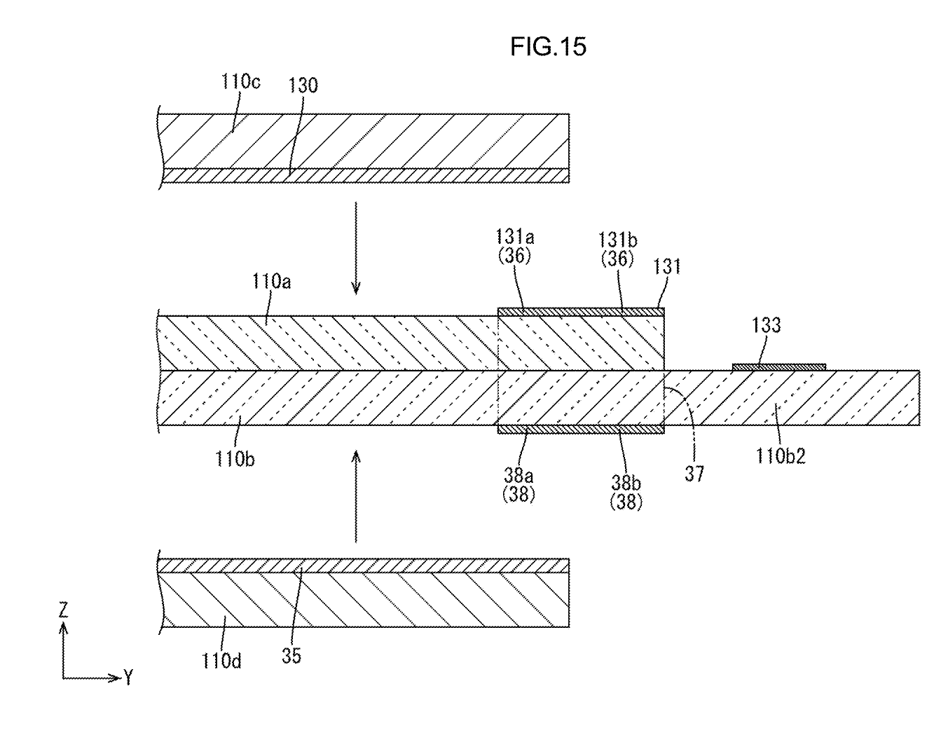

The liquid crystal panel 110 according to this embodiment has the above-described structure and a method of producing such a liquid crystal panel 110 will be described. The conductive member mounting process, a polarizing plate bonding process, and the around member disposing process included in the method producing the liquid crystal panel 110 will be described. In the conductive member mounting process, the conductive member 131 that is previously molded in a folded shape (au-shape) is mounted on the array board 110b and the CF board 110a from a side. As illustrated in FIG. 15, according to the mounting of the conductive member 131, the array board 110b and the CF board 110a are sandwiched between the first connection portion 36 and the second connection portion 38 and the edge surface opposite portion 37 is opposite the edge surfaces of the array board 110b and the CF board 110a while being in contact therewith or close thereto (see FIG. 11).

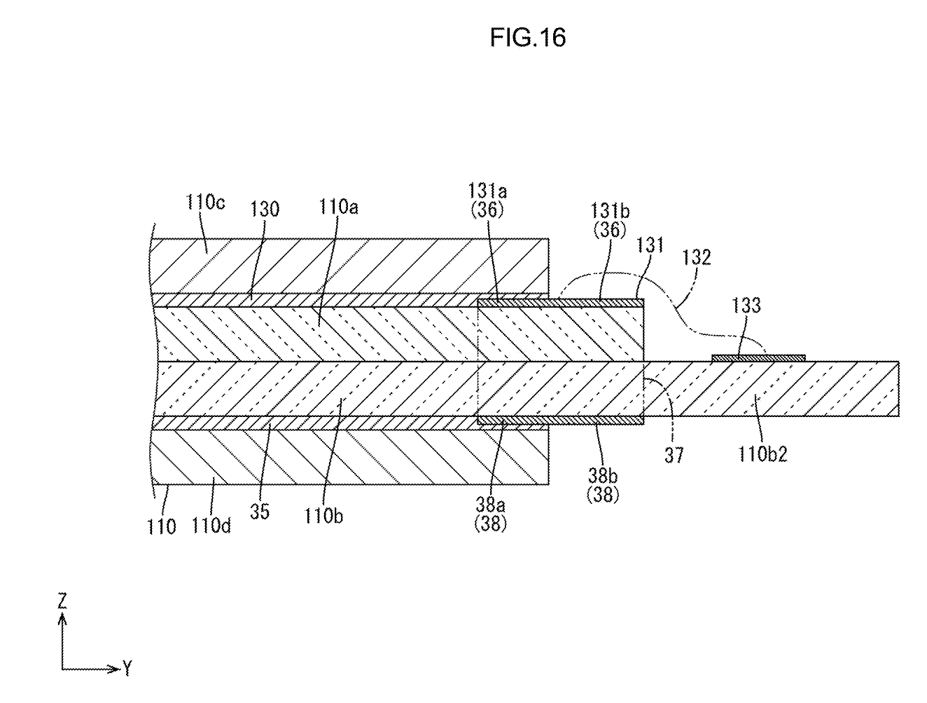

In the polarizing plate bonding process, from the state of FIG. 15, the first polarizing plate 110c and the second polarizing plate 110d are bonded to outer surface sides of the CF board 110a and the array board 110b. After the first polarizing plate 110c is bonded on the outer surface side of the CF board 110a, as illustrated in FIG. 16, a part of the conductive bonding layer 130 overlaps the first polarizing plate overlapping portion 131a of the first connection portion 36 of the conductive member 131 on the outer side (the first polarizing plate 110c side) and a rest of the conductive bonding layer 130 overlaps directly the outer surface of the CF board 110a on the outer side. Accordingly, the electric connection between the conductive bonding layer 130 and the first connection portion 36 of the conductive member 131 is established. After the second polarizing plate 110d is bonded on the outer surface side of the array board 110b, a part of the second conductive bonding layer 35 overlaps the second polarizing plate overlapping portion 38a of the second connection portion 38 of the conductive member 131 on the outer side (the second polarizing plate 110d side) and a rest of the second conductive bonding layer 35 overlaps directly the outer surface of the array board 110b on the outer side. Accordingly, the electric connection between the second conductive bonding layer 35 and the second connection portion 38 of the conductive member 131 is established.

In the ground connection member disposing process, the conductive paste, which is to be the ground connection member 133, is disposed with coating on an area ranging from a first polarizing plate non-overlapping portion 131b of the first connection portion 36 of the conductive member 131 disposed on the outer surface of the CF board 110a to a ground pad 133 disposed on the inner surface of a CF board non-overlapping portion 110b2 of the array board 110b and the disposed conductive paste is cured. Accordingly, as illustrated in FIG. 12, the first connection portion 36 of the conductive member 131 and the ground pad 133 are electrically connected to each other via the ground connection member 132. The first connection portion 36 is connected to the second connection portion 38 via the edge surface opposite portion 37. Therefore, the conductive bonding layer 130 and the second conductive bonding layer 35 are connected to around via the conductive member 131, the ground connection member 132, and the ground pad 133. According to such a configuration, the surface of the CF board 110a is less likely to be charged and static electricity is less likely to remain on the CF board 110a. If noise may affect the array board 110b from the rear side, the array board 110b can be shielded from the noise and display errors are less likely to be caused. The conductive bonding layer 130 and the second conductive bonding layer 35 have sheet resistance that is effectively higher than the sheet resistance of the transparent electrode film. Therefore, in the liquid crystal panel 110 including a built-in touch panel pattern, the touch signals for detecting touching are less likely to be shielded by the conductive bonding layer 130 and the second conductive bonding layer 35, and the function of the touch panel can be optimally exerted. It is preferable to achieve multifunction of the liquid crystal panel 110.

As described above, the present embodiment includes the second polarizing plate 110d bonded to a plate surface of the array board 110b opposite from the CF board 110a side. The second polarizing plate 110d includes the second conductive bonding layer 35 that is to be bonded to the array board 110b. The conductive member 131 includes the first connection portion, the edge surface opposite portion 37, and the second connection portion 38. The first connection portion 36 is disposed on the plate surface of the CF board 110a opposite from the array board 110b side and is connected to conductive bonding layer 130 and the ground connection member 132. The edge surface opposite portion 37 is continuous from the first connection portion 36 and opposite the edge surfaces of the array board 110b and the CF board 110a. The second connection portion 38 is continuous from the edge surface opposite portion 37 and disposed on the plate surface of the array board 110b opposite from the CF board 110a side and overlaps the second conductive member 35 on the array board 110b side. According to such a configuration, the second polarizing plate 110d bonded to the plate surface of the array board 110b opposite from the CF board 110a side is bonded to the array board 110b via the second conductive bonding layer 35. The second conductive bonding layer 35 is connected to the second connection portion 38 of the conductive member 131 that is overlapped on the array board 110b side. The second connection portion 38 continuous to the edge surface opposite portion 37 that is opposite the edge surfaces of the array board 110b and the CF board 110a. The edge surface opposite portion 37 is further continuous to the first connection portion 36 that is connected to the conductive bonding layer 30 and the ground connection member 32. According to such a configuration, the array board 110b is effectively shielded by the second conductive bonding layer 35. Thus, the conductive bonding layer 130, the second conductive bonding layer 35, and the ground connection member 132 are connected to one another via the conductive member 131. The number of components and a cost can be reduced.

The first connection portion 36 and the second connection portion 38 of the conductive member 131 are adjacent to the edge surfaces of the array board 110b and the CF board 110a. According to such a configuration, in comparison to a configuration that the first connection portion and the second connection portion are away from the edge surfaces of the array board 110b and the CF board 110a, the first connection portion 36 and the second connection portion 38 that are continuous from the edge surface opposite portion 37 opposite the edge surfaces of the array board 110b and the CF board 110a can be shortened.

The conductive member 131 is arranged such that the first connection portion 36 overlaps the second connection portion 38. According to such a configuration, in comparison to a configuration that the first connection portion and the second connection portion do not overlap each other, the edge surface opposite portion 37 that is continuous to the first connection portion 36 and the second connection portion 38 can be shortened.

### Third Embodiment

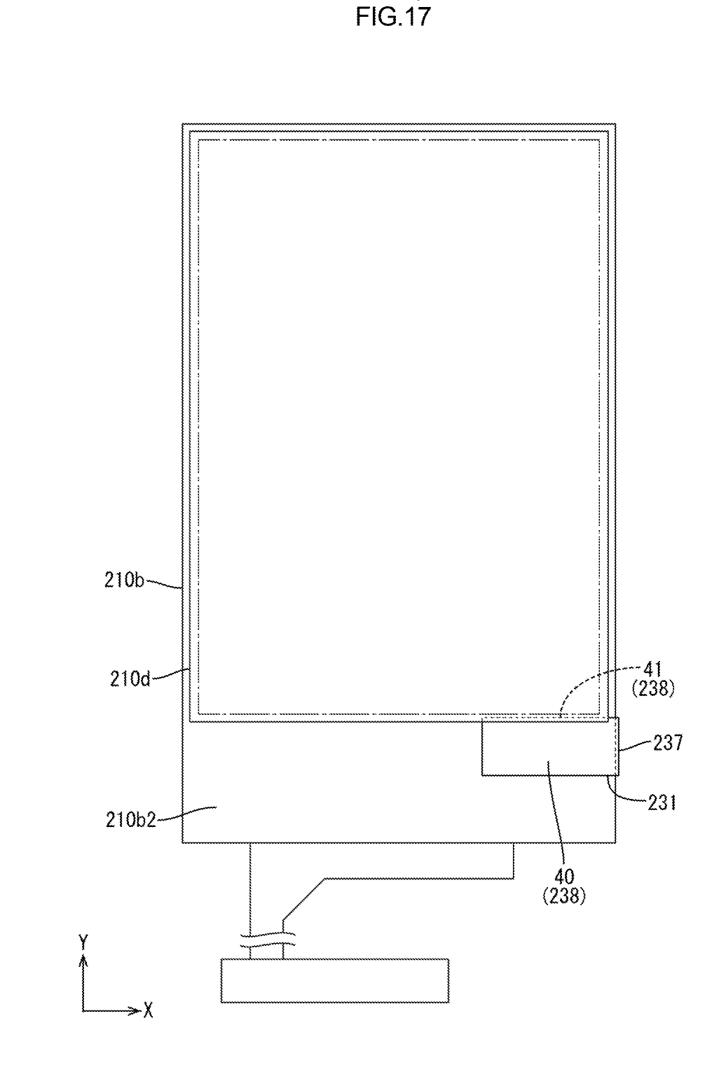

A third embodiment of the present technology will be described with reference to FIGS. 17 to 19. In the third embodiment, a second polarizing plate 210d and a conductive member 231 have configurations that are modified from those of the second embodiment. Configurations, operations, and effects that are similar to those of the second embodiment will not be described.

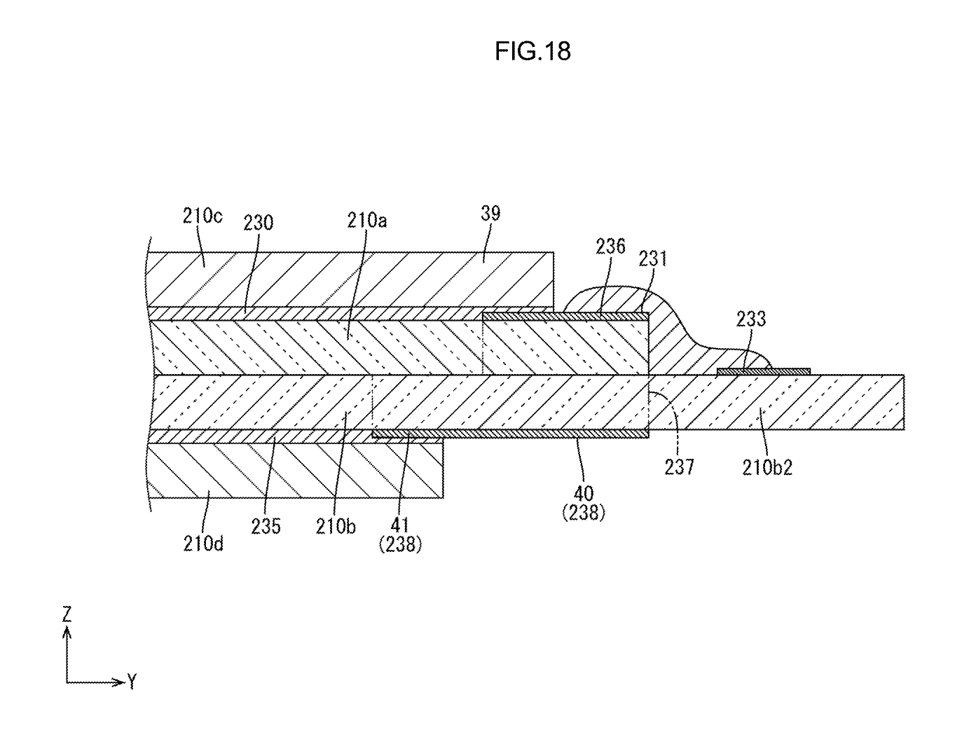

As illustrated in FIGS. 17 and 18, the second polarizing plate 210d of this embodiment has a plan view size smaller than that of a first polarizing plate 210c. An entire area of the second polarizing plate 210d overlaps the first polarizing plate 210c. Specifically, the second polarizing plate 210d has an edge on a lower side in FIG. 17 (on a right side in FIG. 18), which is on a CF board non-overlapping portion 210b2 side, and the edge of the second polarizing plate 210d is on an upper level in FIG. 17 (on a left side in FIG. 18) than that of the first polarizing plate 210c. Therefore, an edge portion of the first polarizing plate 210c on the CF board non-overlapping portion 210b2 side (on the grand pad 233 side) is the second polarizing non-overlapping portion that does not overlap the second polarizing plate 210d. The portion of the conductive bonding layer 230 included in the second polarizing plate non-overlapping portion 39 overlaps the first connection portion 236 of the conductive member 231 to be connected to each other.

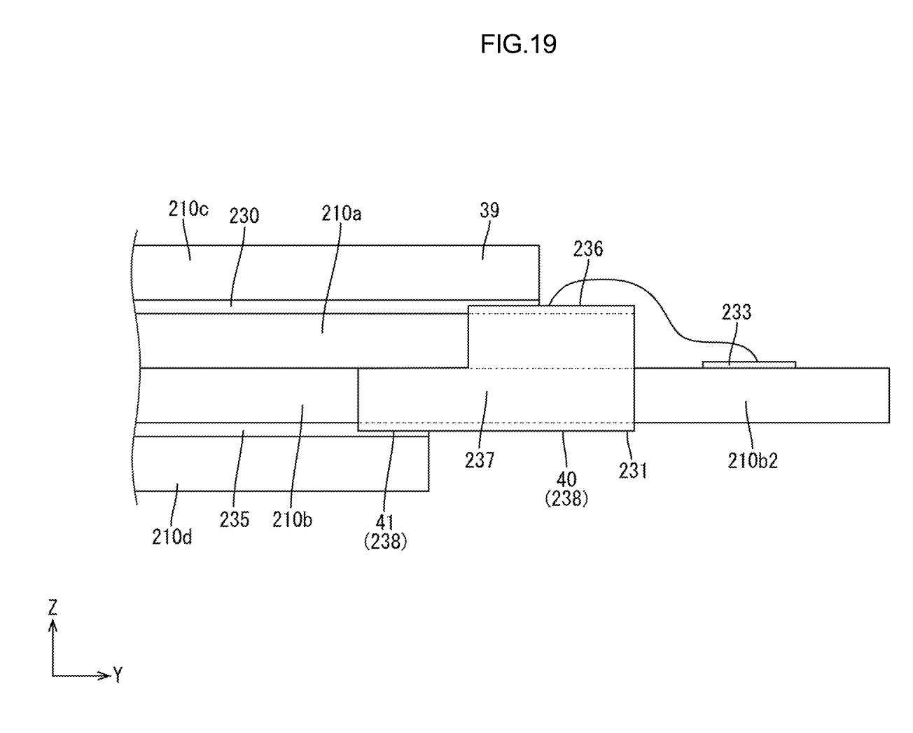

As illustrated in FIGS. 17 and 18, the second connection portion 238 has a plan view size greater than the first connection portion 236. The second connection portion 238 includes a first connection portion overlapping portion 40 and a first connection portion non-overlapping portion 41. The first connection portion overlapping portion 40 overlaps the first connection portion 236 that is to be connected to the conductive bonding layer 230. The first connection non-overlapping portion 41 does not overlap the first connection portion 236. The first connection portion overlapping portion 40 does not overlap the second polarizing plate 210d and the first connection portion overlapping portion 40 partially overlap the second polarizing plate 210d. Therefore, the first connection portion overlapping portion 40 overlaps the second conductive bonding layer 235 included in the second polarizing plate 210d and is connected to the connection portion. As illustrated in FIGS. 18 and 19, an edge surface opposite portion 237 includes a portion continuous to the first connection portion 236 and a portion continuous to the second connection portion 238 that have different dimensions in the Y-axis direction, which is a direction along the opposite surfaces thereof, and the former portion is greater than the latter portion. A boundary between the portion of the edge surface opposite portion 237 continuous to the first connection portion 236 and the portion thereof continuous to the second connection portion 238 substantially matches a bonding surface between the CF board 210a and the array board 210b. As described above, even if the first polarizing plate 210c and the second polarizing plate 210d have a different size, the conductive member 231 formed from the conductive tape can freely form the first connection portion 236 and the second connection portion 238 in various areas. The first connection portion 236 and the second connection portion 238 can be effectively connected to the conductive bonding layer 230 and the second conductive bonding layer 235.

As described before, according to this embodiment, the first polarizing plate 210c, which is one of the first polarizing plate 210c and the second polarizing plate 210d, includes a second polarizing plate non-overlapping portion 39 that does not overlap the second polarizing plate 210d, which is another one of the polarizing plates. Among the first connection portion 236 and the second connection portion 238, the second connection portion 238 (another one of the first connection portion 236 and the second connection portion 238) includes a first connection portion overlapping portion 40 and a first connection portion non-overlapping portion 41. The second connection portion 238 is connected to the second conductive bonding layer 235 included in the second polarizing plate 210d (another one of the polarizing plates), the second conductive bonding layer is one of the conductive bonding layer 230 and the second conductive bonding layer 235. The first connection portion 236 is to be connected to the conductive bonding layer 230, which is another one of the conductive bonding layer 230 and the second conductive bonding layer 235, included in the one first polarizing plate 210c. The first connection portion overlapping portion 40 overlaps the first connection portion 236, and the first connection portion non-overlapping portion 41 does not overlap the first connection portion 236. Even if the first polarizing plate 210c and the second polarizing plate 210d have a different size, the conductive member 231 formed from the conductive tape can freely form the first connection portion 236 and the second connection portion 238 in various areas. The first connection portion 236 and the second connection portion 238 can be effectively connected to the conductive bonding layer 230 and the second conductive bonding layer 235.

### Other Embodiments

The present invention is not limited to the embodiments, which have been described using the foregoing descriptions and the drawings. For example, embodiments described below are also included in the technical scope of the present invention.

(1) In each of the above embodiments, the conductive tape is used as the conductive member. However, a conductive pad formed from a metal film or a transparent electrode film may be used as the conductive member. In a configuration including the conductive pad formed from a transparent electrode film as the conductive member, at least a part of the conductive member can overlap the display area.

(2) In each of the above embodiments, the silver paste is used as the conductive paste of the ground connection member. However, the conductive paste using metal other than silver may be used. Other than the conductive paste, other material such as conductive adhesive may be used as long as it has conductivity and effective deformation degree for forming the ground connection member. The ground connection member may be formed from a conductive tape.

(3) In each of the above embodiments, the ground pad is formed from a metal film. However, the ground pad may be formed from a transparent electrode film or may be formed from a conductive tape.

(4) In each of the above embodiments, the ground connection member is connected to the ground pad. However, the ground pad may not be provided and the ground connection member may be connected to a metal casing (such as a chassis or a bezel) included in a liquid crystal display device such that the conductive member may be connected to ground. In such a configuration, the ground connection member may be preferably formed from a conductive tape.

(5) In each of the above embodiments, the conductive member is mounted on the CF board after the boards are bonded to each other. However, the conductive tape may be mounted on the CF board before the boards are bonded to each other.

(6) In each of the above embodiments, the edge surface opposite portion is directly opposite the edge surfaces of the boards. Another part may be disposed between the edge surface opposite portion and the edge surfaces of the respective boards.

(7) In each of the above embodiments, the conductive member is disposed near the edge surfaces of the boards with respect to the Y-axis direction. The conductive member may be disposed away from the edge surfaces of the boards with respect to the Y-axis direction.

(8) In the second and third embodiments, the conductive member that is previously formed in a U-shape is mounted on the boards. However, the conductive member having a straight shape may be processed to be formed in a U-shape when mounted on the boards.

(9) In the second embodiment, the first connection portion and the second connection portion of the conductive member overlap each other with entire areas thereof. The first connection portion and the second connection portion may overlap each other in parts thereof, respectively, or a part of one of the first connection portion and the second connection portion may overlap another one.

(10) In the third embodiment, the first polarizing plate includes the second polarizing non-overlapping portion. The second polarizing plate may have a greater plan view size than the first polarizing plate and may include the first polarizing plate non-overlapping portion that does not overlap the first polarizing plate. In such a configuration, the first connection portion may include a second connection portion overlapping portion that overlaps the second connection portion to be connected to the second conductive bonding layer and a second connection portion non-overlapping portion that does not overlap the second connection portion. The second connection overlapping portion does not overlap the first polarizing plate and the second connection overlapping portion partially overlaps the first polarizing plate. Therefore, the second connection portion overlapping portion may overlap the conductive bonding layer to be connected.

(11) As a modification of the third embodiment, a boundary between a portion of the edge surface opposite portion continuous to the first connection portion and a portion thereof continuous to the second connection portion may not match a bonding surfaces of the CF board and the array board.

(12) Specific detection methods of a build-in touch panel pattern in a liquid crystal panel according to each of the embodiments may include an electrostatic capacitance type, a contact type, an optical type, a hybrid type, and an electronic paper type, and any of the detection methods can be applied in each of the above embodiments.

(13) in each of the above embodiments, the liquid crystal panel includes the touch panel pattern therein. A structure exerting functions other than the touch panel function may be included in the liquid crystal panel.

(14) In each of the above embodiments, the semiconductor film configuring the channel portion of the TFTs includes the oxide semiconductor material. Polysilicon (polycrystallized silicon (polycrystalline silicon)) such as continuous grain silicon (CG silicon) or amorphous silicon may be used as the semiconductor film.

(15) Each of the above embodiments includes the liquid crystal panel of a lateral electric field type that includes an FFS mode as an operation mode. A liquid crystal panel that includes an in-plane switching (IPS) mode is also included in the scope of the present invention.

(16) In each of the above embodiments, the color filters of the liquid crystal panel include filters of three colors including red, green, and blue. In addition to the red, green and blue color portions, a yellow color portion may be included and the liquid crystal panel including the color filters of four colors is also included in the scope of the present invention.

(17) Each of the above embodiments includes the liquid crystal panels that are classified as small sized or small to middle sized panels. However, liquid crystal panels that are classified as middle sized or large sized (or supersized) panels having screen sizes from 20 inches to 90 inches are also included in the scope of the present invention. Such display panels may be used in electronic devices including television devices, digital signage, and electronic blackboard.

(18) in each of the above embodiments, the liquid crystal panel includes boards and the liquid crystal layer sandwiched therebetween. A liquid crystal panel including the boards and functional organic molecules other than the liquid crystal material is also included in the scope of the present invention.

(19) Each of the above embodiments includes the TFTs as switching components of the liquid crystal display panel. However, liquid crystal display panels that include switching components other than TFTs (e.g., thin film diodes (TFDs)) may be included in the scope of the present invention. Furthermore, black-and-white liquid crystal display panels, other than color liquid crystal display panels, are also included in the scope of the present invention.

(20) in each of the above embodiments, the liquid crystal display panels are described as the display panels. However, other types of display panels (e.g., plasma display panels (PDPs), organic EL panels, electrophoretic display (EPD) panels, micro electro mechanical systems (MEMS) display panels) are also included in the scope of the present invention.

### EXPLANATION OF SYMBOLS

10, 110: liquid crystal panel (display panel), 10a, 110a, 210a: CF board (counter board), 10b, 110b, 210b: array board, 10b2, 110b2, 210b2: CF board non-overlapping portion (counter board non-overlapping portion), 10c, 110c, 210c: first polarizing plate (polarizing plate, one polarizing plate), 10d, 110d, 210d: second polarizing plate (second polarizing plate, another polarizing late), 13: TFT (display component), 30, 130, 230: conductive bonding layer (another one of the conductive bonding layer and the second conductive bonding layer), 31, 131, 231: conductive member, 21a: first polarizing plate overlapping portion (polarizing plate overlapping portion), 31b: first polarizing plate non-overlapping portion (polarizing plate non-overlapping portion), 32, 132: ground connection member, 33, 133, 233: ground pad, 35, 235: second conductive bonding layer (one of the conductive bonding layer and the second conductive bonding layer), 36, 236: first connection portion (another one of the first connection portion and the second connection portion), 37, 237: edge surface opposite portion, 38, 238: second connection portion, AA: display area, NAA: non-display area

1. A display panel comprising:
an array hoard including display components arranged in a matrix;
a counter board bonded to the array board to be opposite the array board;
a polarizing plate bonded to the counter hoard on a plate surface opposite from an array board side, the polarizing plate including a conductive bonding layer that is bonded to the counter hoard;
a conductive member disposed on the plate surface of the counter board opposite from the array board side and overlapping the conductive bonding layer on a counter board side with respect to the conductive bonding layer; and
a ground connection member having one end connected to the conductive member and another end connected to ground.

2. The display panel according to claim 1, wherein
the conductive member includes a polarizing plate overlapping portion that overlaps the polarizing plate and is connected to the conductive bonding layer and a polarizing plate non-overlapping portion_{—} that does not overlap the polarizing plate and is connected to the conductive member.

3. The display panel according to claim 1, wherein
the array board includes a counter board non-overlapping portion that does not overlap the counter board and a ground pad that is connected to ground and disposed on the counter board non-overlapping portion, and
the ground connection member is formed from conductive paste extending from the ground pad to the conductive member.

4. The display panel according to claim 1, wherein
each of the array board and the counter board includes a display area displaying images and a non-display area surrounding the display area, and
the conductive member is disposed in the non-display area.

5. The display panel according to claim 1, wherein the conductive member is formed from a conductive tape.

6. The display panel according to claim 5, further comprising second polarizing plate bonded to the array board on a plate surface opposite from the counter board side and including a second conductive bonding layer bonded to the array board, wherein
the conductive member includes:
a first connection portion disposed on the plate surface of the counter board opposite from the array hoard side and connected to the conductive bonding layer and the ground connection member;
an edge surface opposite portion continuous from the first connection portion and opposite edge surfaces of the array board and the counter board; and
a second connection portion continuous from the edge surface opposite portion and disposed on the plate surface of the array board opposite from the counter board side and overlapping the second conductive bonding layer on the array board side with respect to the second conductive bonding layer.

7. The display panel according to claim 6, wherein the conductive member is arranged such that the first connection portion and the second connection portion are adjacent to the edge surfaces of the array board and the counter board.

8. The display panel according to claim 7, wherein the conductive member is arranged such that the first connection portion and the second connection portion overlap each oilier.

9. The display panel according to claim 6, wherein
one of the polarizing plate and the second polarizing plate includes a portion that does not overlap another one of the polarizing plate and the second polarizing plate, and
one of the first connection portion and the second connection portion that is connected to one of the conductive bonding layer and the second conductive bonding layer included in the other one of the polarizing plate and the second polarizing plate includes a portion overlapping another one of the first connection portion and the second connection portion that is to be connected to another one of the conductive bonding layer and the second conductive bonding layer included in the one of the polarizing plate and the second polarizing plate and a portion not overlapping the other one of the first connection portion and the second connection portion.
